(19) United States
(12) Patent Application Publication
(10) Pub. No.: US 2014/0132429 A1
(43) Pub. Date: May 15, 2014

(54) Method for data compression and inference

(71) Applicant: John Conant Scoville, Santa Cruz, CA (US)

(72) Inventor: John Conant Scoville, Santa Cruz, CA (US)

(21) Appl. No.: 13/674,010

(22) Filed: Nov. 10, 2012

(51) Int. Cl. H03M 13/37

(52) U.S. Cl. CPC H03M 13/37
USPC 341/87

(57) ABSTRACT

Lossless and lossy codes are combined for data compression. In one embodiment, the most significant bits of each value are losslessly coded along with a lossy version of the original data. Upon decompression, the lossless reduced-precision values establish absolute bounds for the lossy code. Another embodiment losslessly codes the leading bits while trailing bits undergo lossy coding. Upon decompression, the two codes are summed. The method preserves edges and other sharp transitions for superior lossy compression. Additionally, the method enables description-length inference using noisy data.

Priority is claimed for application U.S. 61/629,309 ‘Method for data compression and inference’ of Nov. 16, 2011

### TECHNICAL FIELD

The invention pertains to methods for the compression of data and also to the use of data compression to perform inference.

### BACKGROUND ART

There is significant, precedent, both in theory and practice, for separating data into a precisely specified quantity, which is often regarded as a measurement, and an uncertain quantity, which is often regarded as measurement error. The notion of measurement error has been an important part of science for centuries, but only more recently have the fundamental properties of this information been studied and utilized in relation to data compression. We will first discuss the theory of data compression relevant to the present invention and then comment on relevant inventions in the prior art which make use of codes having two or more parts.

In contrast to information-losing or ‘lossy’ data compression, the lossless compression of data, the central problem of information theory, was essentially opened and closed by Claude Shannon in a 1948 paper[13]. Shannon showed that the entropy formula (introduced earlier by Gibbs in the context of statistical mechanics) establishes a lower bound on the compression of data communicated across some channel—no algorithm can produce a code whose average codeword length is less than the Shannon information entropy. If the probability of codeword symbol i is Pᵢ:

S=−kΣPᵢ log Pᵢ

This quantity is the amount of information needed to invoke the axiom of choice and sample an element from a distribution or set with measure; any linear measure of choice must have its analytic form of expected log-probability[13]. This relies on the knowledge of a probability distribution over the possible codewords. Without a detailed knowledge of the process producing the data, or enough data to build a histogram, the entropy may not be easy to estimate. In many practical cases, entropy is most readily measured by using a general-purpose data compression algorithm whose output length tends toward the entropy, such as Lempel-Ziv. When the distribution is uniform, the Shannon/Gibbs entropy reduces to the Boltzmann entropy function of classical thermodynamics; this is simply the logarithm of the number of states.

The entropy limit for data compression established by Shannon applies to the exact (‘lossless’) compression of any type of data. As such, Shannon entropy corresponds more directly to written language, where each symbol is presumably equally important, than to raw numerical data, where leading digits typically have more weight than trailing digits. In general, an infinite number of trailing decimal points must be truncated from a real number in order to obtain a finite, rational measurement. Since some bits have much higher value than others, numerical data is naturally amenable to information-losing (‘lossy’) data compression techniques, and such algorithms have become routine in the digital communication of multimedia data. For the case of a finite-precision numerical datum, rather than the Shannon entropy, a more applicable complexity measure might be Chaitin's algorithmic prefix complexity[2] which measures the irreducible complexity of the leading digits from an infinite series of bits. The algorithmic prefix complexity is an example of a Kolmogorov complexity[9], the measure of minimal descriptive complexity playing a central role in Kolmogorov's formalization of probability theory.

Prior to the twentieth century, this basic notion of a probability distribution function (pdf) had not changed significantly since the time of Gauss. After analysis of the Brownian motion by Einstein and others, building on the earlier work of Markov, the stochastic process became a popular idea. Stochastic processes represent the fundamental, often microscopic, actions which lead to frequencies tending, in the limit, to a probability density. Stochastic partial differential equations (for example, the Fokker-Planck equation) generate a pdf as their solution, as do the ‘master equations’ from whence they are derived; such pdfs may describe, for instance, the evolution of probabilities over time. They were used notably by Langevin to separate dynamical systems into a deterministic classical part and a random stochastic component or statistical model. Given empirical data from such a system, the Langevin approach may be combined with the maximum likelihood method[4] or Bayesian inference (maximum posterior method) to identify the most likely parameters for an unknown noise function.

In practice, Langevin's approach either posits the form of a noise function or fits it to data; it does not address whether or not data is stochastic in the first place. Kolmogorov addressed this issue, refining the notion of stochastic processes and probability in general. Some objects, a solid black image, for example, are almost entirely regular. Other data seem totally random; for instance, geiger counters recording radioactive decays. Stochastic objects lay between these two extremes; as such, they exhibit both deterministic and random behavior. Kolmogorov introduced a technique for separating a message into random and nonrandom components. First, however, he defined the Kolmogorov complexity, C(X). C(X) is the minimum amount of information needed to completely reconstruct some object, represented as a binary string of symbols, X[3, 9].

$${C}_{f} ( X ) = {min}_{f ( p ) = X} \vert p \vert$$

The recursive function f may be regarded as a particular computer and p is a program running on that computer. The Kolmogorov Complexity is the length of the shortest computer program that terminates with X as output on computer f. In this way, it symbolizes perfect data compression. For various reasons (such as the non-halting of certain programs), it is usually impossible to prove that non-trivial representations are minimal. On the other hand, a halting program always exists, the original string, so a minimal halting program also exists, even if its identity can't be verified. In practice, the Kolmogorov complexity asymptotically approaches the Shannon entropy[9], and the complexity of typical objects may be readily approximated using the length of an entropic code.

Often, a variant of Kolmogorov complexity is used—Chaitin's algorithmic prefix complexity K(X)[2] which considers only self-delimiting programs that do not use stop symbols. Since a program may be self-delimiting by iteratively prefixing code lengths, K(X)=C(X)+C(C(X))+O(C(C(C(X))))[9]

Returning to the separation of signal and noise, we now define stochasticity as it relates to the Kolmogorov structure function. For natural numbers k and δ, we say that a string x is (k,δ)-stochastic if and only if there exists a finite set A such that:

xεA,C(A)≦k,C(x|A)≧log |A|−δ

The deviation from randomness, δ, indicates whether x is a typical or atypical member of A. This is minimized through the Kolmogorov Structure Function, Cₖ(x|n):

Cₖ(x|n)=min{log |A|:xεA,C(A|n)≦k}

The minimal set A₀ minimizes the deviation from randomness, δ, and is referred to as the Kolmogorov Minimal Sufficient Statistic for x given n. The Kolmogorov Structure Function specifies the bits of additional entropy (Shannon entropy reduces to the logarithm function for a uniform distribution) necessary to select the element x from a set described with k or fewer bits. For a regular object, the structure function has a slope less than −1. Specifying another bit of k reduces the entropy requirement by more than a bit, resulting in compression. Beyond a critical threshold, corresponding to the minimal sufficient statistic, stochastic objects become random. Beyond this point, specifying another bit of k increases the entropy by exactly one bit, so the slope of the structure function reaches its maximum value of −1. For this reason, Kolmogorov identified the point at which the slope reaches −1 as the minimal sufficient statistic. The Kolmogorov minimal sufficient statistic represents the amount of information needed to capture all the regular patterns in the string x without literally specifying the value of random noise.

While conceptually appealing, there are practical obstacles to calculating the Kolmogorov minimal sufficient statistic. First, since the Kolmogorov complexity is not directly calculable, neither is this statistic. Approximations may be made, however, and when using certain common data compression algorithms, the point having slope 1 is actually a reasonable estimate of the onset of noise. When certain data are compressed more fully, however, this point may not exist. For example, consider a color photograph of black and white static on an analog TV set. The pattern of visible pixels emerges from nearly incompressible entropy; chaos resulting from the machine's attempt to choose values from a nonexistent signal. Since a color photograph has three channels, and the static is essentially monochrominancetic; the channels are correlated to one another and hence contain compressible mutual information. As such, the noise in the color photograph, though emergent from essentially pure entropy, is intrinsically compressible—hence, the compression ratio never reaches 1:1 and the Kolmogorov minimal sufficient statistic does not exist.

Instead of the parameter value where the compression ratio reaches 1:1, which may not exist, one often seeks the parameter value which provides the most information about the object under consideration. The problem of determining the most informative parameters in a model was famously addressed by the statistician R. A. Fisher[4].

The Fisher Information quantifies the amount of information expected to be inferred in a local neighborhood of a continuously parameterizable probability distribution. The Fisher Information quantifies information at specific values of the parameters—it quantifies the informativeness of a local observation.

If the probability density of X is parameterized along some path by t, f(X;t), then the Fisher Information Metric at some value of t is the expectation of the variance of the Hartley information[6], also known as the score:

I(t)=−E[(∂ₜ ln ƒ(X;t))²|t]

The Fisher Information quantifies the convexity (the curvature) of an entropy function at a specific point in parameter space, provided sufficient regularity and differentiability.

In the case of multiple parameters, the Fisher Information becomes the Fisher Information Metric (or Fisher Information Matrix, FIM), the expected covariance of the score:

I(t)ᵢⱼ=E[∂_{tdi i} ln ƒ(X;t)∂ₜ_{ⱼ} ln ƒ(X;t)]

The Fisher-Rao metric is simply the average of the metric implied by Hartley information over a parameterized path. The space described by this metric has distances that represent differences in information or entropy. The differential geometry of this metric is sometimes called information geometry. We seek the parameter values maximizing the Fisher-Rao metric, for variations in these values lead to the largest possible motions in the metric space of information.

If we take ƒ(X; t) to be the universal probability of obtaining a string X from a randomly generated program on a universal computer, this probability is typically dominated by the shortest possible program, implying that ƒ(X;t)≈2^{-K(X)}, where we have used K(X) instead of C(X) so the sum over all X will convergence to unit probility[9]. If we make the string X a function of some parameter t, X=X(t), then ƒ(X;t)≈2^{-K(X(t))}, the Hartley information is ln 2 times −K(X(t)), and its associated Fisher-Rao metric is:

I(t)ᵢⱼ≈(ln 2)²E[∂ₜ_{ᵢ}K(X(t))∂ₜ_{ⱼ}K(X(t))]

Since the spaces we consider are generally discrete, we will consider paths from one parameter value to the next and evaluate partial differences in place of the partial derivatives. The one-dimensional Fisher information of a path from n to n+1 is, replacing the continuous differentials with finite differences, and ignoring the expectation operator, which becomes the identity operator since the expectation covers only one point:

I(t)=2 ln 2(K(X(t+1)−K(X(t)))², 0<n<d

Maximizing this quantity is equivalent to maximizing K(X(t+1)−K(X(t)), which is also the denominator in the slope of the Kolmogorov structure function. For incompressible data, the numerator log |Aₜ|-log |Aₜ₋₁| (which is the number of additional bits erased by the uncompressed X(t) beyond those erased by the more descriptive X(t+1)) also takes on this value. Since the parameter in the Kolmogorov structure function corresponds to bits of description length, the literal description corresponding to each subsequent parameter value differs in length by a constant, minimizing the slope of the Kolmogorov structure function is equivalent to maximizing K(X(t+1)−K(X(t)) and the Fisher information. The minimal parameter that maximizes the Fisher information is the Kolmogorov minimal sufficient statistic.

Sometimes, rather than considering the point at which a phase transition is complete, we wish to consider the critical point at which it proceeds most rapidly. For this, we use the expectation of the Hessian of the Hartley information:

J(t)ᵢⱼ=E[∂ₜ_{ᵢ}² ln ƒ(X;t)∂ₜ_{ⱼ}² ln ƒ(X;t)]

This is in contrast to the expectation of the Hartley information, the entropy, or the expected curvature of the Hartley information, the Fisher information. When this function is maximized, the Fisher information (or slope of the Kolmogorov structure function) is changing as rapidly as possible. This means that the phase transition of interest is at its critical point and proceeding at its maximum rate. Beyond this point, the marginal utility of each additional bit decreases as the phase transition proceeds past criticality to completion at the minimal sufficient statistic.

The derivatives in the Fisher information were approximated using backwards differences in complexity; however, a forward second difference may applied subsequently to complete the Hessian, the net result of this is a central difference approximation to the second derivative of complexity: ∂ₜ_{ᵢ}²K(A^{t}^{ᵢ})≈K(A^{t+1})−2K(A^{t})+K(A^{t-1}). The maximum resulting from this approximation is between the maximum and minimum values of the parameter, exclusively.

In practice, since we can't calculate K(X) exactly, it is helpful to treat any value of the Fisher information (or the slope of the Kolmogorov structure function) within some tolerance of the maximum K(Xⁿ)−K(Xⁿ⁻¹) as being a member of a nearly-maximum set, and select the element of this set having the fewest bits. Usually, the representation having the lowest complexity is the one with the lowest bit depth or, resolution, but not always—when lossless compression is applied to highly regular objects, the lossless representation may be simpler than any 2-part or purely lossy code. This statistic the represents all the bits of signal that can be described before additional bits require a nearly maximal description—it quantifies the minimum complexity needed to complete a phase transition from a low-complexity periodic signal to a high-complexity chaotic one. This also applies to the maximum of the second derivative, as considered above. Any value of the Hessian that is within some tolerance of the maximal K(A^{t+1})−2K(A^{t})+K(A^{t-1}) is considered part of a nearly-maximal set, and the simplest element of this set is selected as the critical point.

The sufficiency of a statistic was also defined by Fisher in 1921[4]. If a statistic is sufficient, then no other statistic provides any additional information about the underlying distribution. Fisher also demonstrated the relationship between maximum likelihood and sufficient statistics. The Fisher-Neyman factorization theorem says that for a sufficient statistic T(x), the probability density ƒ_{θ}(x) factors into terms dependent and independent of the parameter: ƒ_{θ}(x)=h(x)g_{θ}(T(x)). The maximum likelihood function for the parameter θ depends only the sufficient statistic T(x). As a result, a sufficient statistic is ideal for determining the parameters of a distribution using the popular method of maximum likelihood estimation (MLE). The most efficient possible articulation of a sufficient statistic is a minimal sufficient statistic. A sufficient statistic S(x) is minimal if and only if, for all sufficient statistics T(x), there exists a function f such that S=ƒ(T(x)).

Partitioning the information content of a string into the complexity of its signal and the entropy of its noise is a nuanced idea that takes on several important forms, another is the algorithmic entropy[15, 9] H(Z) of a string. This is defined in its most basic form as:

H(Z)=K(Z)+S

In this context, Z=X_{1:m} is a description of a macroscopic observation constructed by truncating a microscopic state X to a bit string of length m. K(Z) is the algorithmic prefix complexity[2, 9] of this representation, and S=log₂ n is the Boltzmann entropy divided by its usual mulplicative constant, k, the Boltzmann constant, and ln 2, since we are using base 2. n is the logarithm of the multiplicity or volume of truncated states, having universal recursive measure 2^{-m}, so S=−m and the algorithmic entropy is H(Z)=K(Z)−m. This function is also known as the Martin Löf universal randomness test and plays a central role in the theory of random numbers.

The partitioning of a string into signal and noise also allows the determination of the limit to its lossy compression[12], relative to a particular observer. If P(X) is the set of strings which some macroscopic observer P cannot distinguish from string X, then the simplest string from this set is the minimal description equivalent to X:

$${S}_{f} ( X / P ) ≡ {min}_{f ( p ) ∈ P ( X )} \vert p \vert$$

We refer to this complexity as the macrostate complexity[12] or macrocomplexity since its criterion of indistinguishability corresponds to the definition of a macrostate in classical thermodynamics; a macrostate is a set of indistinguishable microstates. Likewise, its entropy function has the form (logarithm of cardinality) of the Boltzmann entropy; it may be shown that if the probability p(X) of the class P is dominated by the shortest program in the class such that p(X)≈2^{-K(X)}, the macrocomplexity S(X/P) is approximately:

K(X)≈S(X/P)+log |X/P|

This first-order approximation to macrocomplexity is close to the effective complexity of Gell-Mann and Lloyd[5]. The effective complexity, Y, is summed with the Shannon entropy, I, or an even more general entropy measure, such as Rényi entropy, to define an information measure, the total information Σ=Y+I, that is typically within a few bits of K(X)[5].

We will now discuss some related data compression schemes. The prior art contains several instances of data compression algorithms which decompose signals into two or more separate encodings. For example, the Scalable Video Coding extension of the H.264 video codec allows the decomposition of a high-quality signal into subset streams which can have different frame rates, resolution, or lossy coding bitrates. A low-quality stream may be encoded to encode basic image data (the ‘Base Layer’) and a higher-quality stream (the ‘Enhancement Layer’) may be encoded using less information than would otherwise be necessary due to the fact that the lower-quality representation helps to predict the high-quality one. This allows flexibility with regard to encoding targeting various end-user applications at multiple resolutions and frame rates.

Early schemes for the transmission of image data via FAX machines used an ad-hoc sampling approach to two-part coding—in one such scheme the first three bits are compressed losslessly using run-length encoding, while the values of less significant bits were not stored for every pixel—less significant pixels being sampled progressively less frequently.

Leading bits tend to be more compressible than trailing bits. There are deep mathematical reasons for this, such as Benford's Law—leading digits tend to be logarithmically distributed while trailing digits tend to approach an incompressible uniform distribution. Furthermore, there is often noise intrinsic to the measurement process which influences trailing bits. Being random, this noise tends to be mostly incompressible. Schemes for the transmission of video data have been proposed to truncate one or more trailing bits, as they are typically noisy and incompressible, storing either a majority truncated bit or other information about this noise. The practical issue with treating data as noise is a degradation in signal quality—replacing the trailing bits with estimates of noise tends to destroy any signal which remains in these bits. Since the trailing bits tend to a weak signal corrupted by noise, a lower level of information loss (and improved overall signal to noise ratio) is obtained by the present invention via lossy coding of the trailing bits.

The lossy coding of error or residual values also has historical precedent, for example, so-called pyramid codes would perform lossy coding of data, calculate the error of the lossy representation, perform lossy coding of the error function, determine the error associated with coding of the error, lossy code this second error function, and so forth until the magnitude of the error reached an acceptable level. This approach to lossy coding is less prevalent now that progressive codes can be coded or transmitted at whatever quality rate or bitrate is desired. One aspect of the present invention is a variation on the theme of compressing residual errors—a lossless representation is made at a lower precision and the error associated with this reduced precision is compressed using a lossy coding scheme, allowing compensation during the decompression process.

### SUMMARY OF INVENTION

### Technical Problem

Critical data compression codes the most significant bits of an array of data losslessly, since they are typically redundant, and either fits a statistical model to the remaining bits or compresses them using lossy data compression techniques. Upon decompression, the significant bits are decoded and added to a noise function which may be either sampled from a noise model or decompressed from a lossy code. This results in a representation of data similar to the original. This type of scheme is well-suited for the representation of noisy or stochastic data.

Attempting to find short representations of the specific states of a system which has high entropy or randomness is generally futile, as chaotic data is incompressible. As a result, any operation significantly reducing the size of chaotic data must discard information, and this is why such a process is colloquially referred to as ‘lossy’ data compression.

Today, lossy compression is conventionally accomplished by optionally preprocessing and/or partitioning data and then decomposing data blocks into coefficients of a set of basis functions. This is generally accomplished by an inner product transformation projecting the signal vector onto a set of basis vectors. The Fourier transform is the canonical example of this procedure, and wavelet transformations involve inner products as well. However, this is not necessarily a valid operation if the underlying variables are stochastic. Stochastic variables are not generally square-integrable, meaning that their inner products do not technically exist. Though a discrete Fourier transform may be applied to a stochastic time series sampled at some frequency, the resulting spectrum of the sample will not generally be the spectrum of the process, as Parseval's theorem need not apply in the absence of square-integrability.

Worse, Fourier transforms such as the discrete cosine transform (DCT) are not the appropriate set of basis vectors to describe light waves being emitted or reflected from particular geometries. A photograph is literally a graph of a cross-section of a solution to Maxwell's equations. The first photographs were created by the absorption of photons on a silver chloride surface, for instance. While it is true that the solution to Maxwell's equations in a vacuum take the form of sinusoidal waves propagating in free space, a photograph of a vacuum would not generally be very interesting and, furthermore, the resolution of macroscopic photographic devices is nowhere close to the sampling frequency needed to resolve individual waves of visible light, which typically have wavelengths of a few hundred nanometers. In a limited number of circumstances, this is appropriate—for example, a discrete cosine transformation would be ideal to encode photons emerging from a diffraction grating with well-defined spatial frequencies. In general, however, most photographs are sampled well below the Nyquist rate necessary to reconstruct the underlying signal, meaning that microscopic detail is being lost to the resolution of the optical device used. Though the sine and cosine functions are orthogonal, they are complete in the sense that they may be used as a basis to express any other function. However, since sinusoids do not generally solve Maxwell's equations in the presence of boundary conditions, the coefficients of such an expansion do not correspond to the true modes that carry energy through the electromagnetic field. The correct set of normal modes—which solve Maxwell's equations and encode the resulting light wave—will be eigenfunctions or Green's functions of the geometry and acceleration of charges[7]. For example, when designing waveguides (for example, fiber optics) the choice of a circular or rectangular cross-section is crucially important as this geometry determines whether the electric or the magnetic field is allowed to propagate along its transverse dimension. Calculating the Fourier cosine transform of these fields produces a noisy spectrum; however, expanding over transverse electric and magnetic modes could produce an idealized spectrum that has all of its intensity focused into a single mode and no amplitude over the other modes. The proper, clean spectrum is appropriate for information-losing approximations—since the (infinite) spectrum contains no energy beyond the modes under consideration, it can be truncated without compromising accuracy. For the complex electronic geometries and motions that comprise interesting real-world photograph, these modes may be difficult to calculate, but they still exist as solutions of Maxwell's equations. Attempting to describe them using sinusoids that don't solve Maxwell's equations leads to incompressible noise and spectra that can't be approximated accurately.

For audio, however, we note that the situation is somewhat different. Audio signals have much lower frequency than visible light, so they are sampled above the Nyquist rate. 44,100 Hz is a typical sampling rate which faithfully reconstructs sinusoids having frequency components less than 22,050 Hz, which includes the vast majority of audible frequencies. Auditory neurons will phase-lock directly to sinusoidal stimuli, making audio perception particularly suitable for Fourier-domain signal processing. If compressed in the time domain, the leading bits (which exhibit large, rapid oscillations) often appear more random to resource-limited data compressors than the leading bits of a Fourier spectrum. At the same time, the less-important trailing bits are often redundant, given these leading bits, owing to vibrational modes which vary slowly compared to the sampling rate. This reverses the trend observed in most images—their most significant bits are usually smoother and more redundant than trailing bits. In the strictly positive domain of Fourier-transformed audio, however, the leading bits become smoother, due the use of an appropriate sampling rate. For macroscopic photographic content, however, individual waves cannot be resolved, making Fourier-domain optical processing less effective.

Nonetheless, scientists and engineers in all disciplines all over the world successfully calculate Fourier transforms of all sorts of noisy data, and a large fraction (if not the vast majority) of all communication bandwidth is devoted to their transmission. JPEG images use discrete cosine transforms, a form of discrete Fourier transform, as does MP3 audio and most video codecs. Other general-purpose transformations, such as wavelets, are closely related to the Fourier transform and still suffer from the basic problem of projecting stochastic data onto a basis—the inner products don't technically exist, resulting in a noisy spectrum. Furthermore, since the basis used doesn't generally solve Maxwell's equations, finite-order approximations that truncate the spectrum will not translate into results that are accurate to the desired order. As such, we seek an alternative to expanding functions over a generic basis set.

### Solution to Problem

The limit of lossy data compression is the Kolmogorov complexity of the macrostate perceived by the observer[12]. Explicitly describing the macrostates perceptually coded by a human observer is prohibitively difficult, which makes optimal compression for a human observer intractable, even if the complexity were exactly calculable. However, the truncation of data which appears in the definition of prefix complexity provides a very natural means of separating 2-part codes, the prefix complexity appears in the definition of the algorithmic entropy[15], which is a special case of macrostate complexity. Truncation of amplitude data provides a simple but universal model of data observation—an observer should regard the most significant bits of a datum as being more important than its least significant bits.

The codes described in this paper are the sum of a truncated macrostate, Z=X_{1:m}, which we call the signal, as well as a lossy approximation of the bits that were truncated from this signal, which we will refer to as that signal's residual noise function. This is in contrast to the algorithmic entropy, which combines a truncated macrostate with all the information needed to recover its microstate. If n samples are truncated from d bits to m, the Boltzmann entropy is proportional to S˜log 2^{n(d-m)}=n(d−m) and the algorithmic entropy is H(Z)=K(Z)+S=K(Z)+n(d−m), however, since we only store K (Z) bits using lossless compression, the savings resulting from a two-part code (compared to a lossless entropic code) could approach the Boltzmann entropy n(d−m) in the case of a highly compressed lossy representation.

First, the bits of datum Y are reordered in the string X, from most significant to least significant. This simplifies truncation and its correspondence to the conditional prefix complexity. The resulting string is truncated to various depths, and the compressibility of the resulting string is evaluated. The point beyond which the object has attains maximum incompressibility also maximizes the Fisher information associated with the distribution P(X)=2^{-K(X)}. As discussed in the previous section, this phase transition proceeds at its maximum rate when the expected Hessian of the Hartley information, J(t), is maximal.

Since the phase transition between periodicity and chaos is generally somewhat gradual, several possible signal depths could be used, to varying effect. Following Ehrenfest's categorization of critical points by the derivative which is discontinuous, we will also refer to critical points by the order of derivatives. Due to the discrete nature of our analysis, our difference approximations never become infinite, instead, we seek the maxima of various derivatives of the information function.

In the first-order approximation to the universal probability, the Hartley information is simply the complexity log P(X)=−K(X), therefore, multiplying the problem by −1, we classify critical points by the derivatives of complexity which have minima there. The first of these, I(t), corresponds to the Fisher-Rao metric, and its maxima correspond to sufficient statistics. If the object is chaotic beyond some level of description, then this level is also the Kolmologorov minimal sufficient statistic. The second order matrix, J(t), is the point at which the Fisher Information increases most rapidly and hence the point beyond which descriptional complexity results in diminishing returns. Higher-order critical points may be considered as well, but become progressively more difficult to determine reliably in the presence of imperfect complexity estimates, so we will analyze only the first two orders.

The choice of a first order critical point (max I(t)) or a second order critical point (max J(t)) as a cutoff for data compression will reflect a preference for fidelity or economy, respectively. Other considerations may lead to alternative signal depths—the mean squared errors of images having various cutoffs are considered in the examples section, for instance. Regardless of the critical point chosen, the redundant, compressible signal component defined by the selected cutoff point is isolated and compressed using a lossless code.

Ideally, an accurate statistical model of the underlying phenomenon, possibly incorporating psychological or other factors, would be fit to the noise component using maximum likelihood estimation to determine the most likely values of the parameters of its distribution. Instead of literally storing incompressible noise, the parameters of the statistical model are stored. When the code is decompressed, the lossless signal is decompressed, while the noise is simulated by sampling from the distribution of the statistical model. The signal and simulated noise are summed, resulting in an image whose underlying signal and statistical properties agree with the original image.

Since statistical modeling of general multimedia data may be impractical, ‘lossy’ data compression methods may be applied to the noise function. A successful lossy representation may be regarded as an alternate microstate of the perceived noise macrostate; it is effectively another sample drawn from the set of data macroscopically equivalent to the observed datum[12]. As such, in the absence of an appropriate model, the noise function is compressed using lossy methods, normalized such that the resulting intensities do not exceed the maximum possible amplitude. This representation will be decompressed and added to the decompressed signal to reconstruct the original datum.

This has several advantages. First, the signal is relatively free of spurious artifacts, such as ringing, which interfere with the extraction of useful inferences from this signal. Artifacts from lossy compression cannot exceed the amplitude of the noise floor, and higher levels of lossy compression may be used as a result of this fact. Furthermore, lossy compression algorithms tend to compress high frequencies at a higher level than lower frequencies. The eyes and ears tend to sense trends that exhibit change over broader regions of space or time, as opposed to high-frequency oscillations. The compressibility of signal and noise leads to an information-theoretic reason for this phenomenon—the former naturally requires less of the nervous system's communication bandwidth than the latter.

The compression ratios afforded by such a scheme can be dramatic for noisy data. As a trivial example, consider a string containing only random noise, such as the result of n independently distributed Bernoulli trials having probability p=0.5, such as a coin flip. Lossless entropic compression cannot effectively compress such a string. Decomposing such a string into basis functions, such as the Fourier amplitudes or wavelets used in the JPEG algorithms, inevitably results in a mess of spurious artifacts with little resemblance to the original string. The critical compression scheme described, however, easily succeeds in reproducing noise that is statistically indistinguishable from (though not identical to) the original string. Furthermore, all that needs to be stored to sample from this distribution is the probability p=0.5 of the Bernoulli trial, which has complexity O(1). The observer for which this scheme is optimal makes statistical inferences of amplitude in a manner similar to a physical measurement. The observer records the statistics of the data, e.g. mean, variance, etc., rather than encoding particular data, which could introduce bias.

If the data is a waveform sampled at a frequency exceeding its effective Nyquist rate, such as an audio recording sampled at more than twice the frequency of a listener's ear, then its spectrum may be analyzed rather than its time series. This will make the data smoother and non-negative, resulting in better compression for the leading bits. In practical terms, this means that we may compress audio by compressing an one-dimensional image which is a graph of its spectrum, or the spectrum of some portion of the time series. Hence, we will develop the method using images as a canonical example, with the understanding that audio may be compressed, for example, using 1-d images of Fourier transforms, and that video may be compressed using an array having the third dimension of time, or by embedding information into lower-dimensional arrays.

For many photographic and video applications, it is conventional to rotate a pixel's RGB color space to a color space, YC_{b}Cᵣ, which more naturally reflects the eye's increased sensitivity to brightness as compared to variations in color. This is normally done in such a way that takes into account the perceived variations in brightness between different phosphors, inks, or other media used to represent color data.

The Y or luminance channel is a black-and-white version of the original image which contains most of the useful information about the image, both in terms of human perception and measurements of numerical error. The luminance channel could be said to be the principal component (or factor) of an image with respect to perceptual models. The blue and red chrominance channels (C_{b} and Cᵣ, respectively) effectively blue-shift and/or red-shift white light of a particular brightness; they are signed values encoding what are typically slight color variations from the luminance channel. It is conventional for the luminance channel to receive a greater share of bandwidth than the less important chrominance channels, which are often downsampled or compressed at a lower bitrate.

As an alternative to consistently using a perceptual model optimized for the output of, for example, particular types of monitors or printers, one could use a similar approach to determine the principal components of color data as encoded rather than perceived. Principal components analysis, also called factor analysis, determines linear combinations of inputs which have the most influence over the output. In principal components analysis, n samples of m-channel sample data are placed in the columns of an m-by-n matrix A and the matrix product AA^{T} is constructed to obtain an m-by-m matrix. The eigenvectors of AA^{T} having the largest eigenvalues are the most influential linear combinations of data, the magnitude of these eigenvalues (sometimes called factor weights) reflects the importance of a particular combination.

The result of applying principal components analysis to photographic content leads to a customized color space whose principal component is a luminance channel whose channel weights correspond to the eigenvector having the largest eigenvalue. This channel is best communicated at a higher bitrate than the secondary and tertiary components, which are effectively chrominance channels. Critically compressing photographs in RGB format has been compared against compression using a critical luminance channel with lossy chrominance channels. For most of these photographs, a critically compressed luminance channel leads to more efficient representations than using only lossy wavelet transformations.

In general, perceived output may be optimized by analyzing the principal components of perceived rather than raw data. In contrast, directly applying principal component analysis (or factor analysis) to the raw data leads to a universal coordinate system for sample space which has improved compressibility, albeit optimized for a particular instance of data rather than the perceived output of a particular medium. In addition to improved compression, another advantage of this approach is that it applies to a wide variety of numerical data and this facilitates a general approach to lossy data compression.

The critical bit depth determines the level of compressible content of a signal. We now determine expressions for the first and second order critical depths. This will allow us to separate signal from noise for audio, image, and video data by determining a bit depth that effectively separates signal from noise. If higher compression ratios are desired, a supercritical signal may be used, meaning that more bits may be truncated, at the cost of destroying compressible information and potentially impeding inference. On the other hand, a signal retaining nearly all of its bits would necessarily be similar to the original.

For a string which encodes the outcome of a series of independent Bernoulli trials (coin flips, for instance) as zeros and ones, each bit constitutes the same amount of information—one bit is one sample. For a string comprised of a series of numeric samples at a bit depth greater than one, this is not usually the case. In the traditional representation of numerals, leading bits are generally more informative than trailing bits, so an effective lossy data compression scheme should encode leading bits at a higher rate. From the viewpoint of compressibility, on the other hand, the smooth, redundant leading bits of a typical stochastic processes are more compressible than its trailing bits. Since the leading bits of multi-bit samples are often more compressible and more significant than the trailing bits, they are candidates for exact preservation using lossless data compression. Since the trailing bits are generally less important and also less compressible, lossy compression can greatly reduce their descriptive complexity without perceptible loss.

Since images will be easy to illustrate in this medium, and provide a middle ground as compared to one or three dimensions for audio or video, respectively, we will treat the two-dimensional case first. We will then generalize to data having any number of dimensions. We will refer to the matrices (rank-2 tensors) as images, since this is a canonical and intuitive case, but these expressions apply generally to all two-dimensional arrays of binary numbers.

Let X_{i,j}^{d} represent a tensor of rank three (a tensor of rank n is an n-dimensional array) representing one channel of a bitmap image. Subscript indices i and j represent x and y coordinates in the image, and the superscript d indexes the bits encoding the amplitude of pixel (i,j) in the channel, ordered from most significant to least significant.

Let the set Aⁿ contain all the images whose leading bits agree with those of X_{i,j}^{d}:

Aⁿ≡{Yᵢⱼ^{m}:Yᵢⱼ^{m}=Xᵢⱼ^{m}, m≦n≦d}

This set can be represented as the original image channel with bit depth truncated from d to n. The implied observer sees n significant bits of (learnable) signal and d−n insignificant bits of (non-learnable) noise. For reference, the algorithmic entropy of the truncated string is:

H(Z)=K(Aⁿ)+log |Aⁿ|=K(Aⁿ)+ijd−ijn

The literal length of the reduced image is ijd−ijn, and most of this will be saved in a critical compression scheme, as noise can be coded at a high loss rate. If Bⁿ is the lossy representation, the complexity of the critically compressed representation is:

K=K(Aⁿ)+K(Bⁿ)≦K(Aⁿ)+ijd−ijn

We may now consider the Fisher information (and hence the minimal sufficient statistic) of Aⁿ. The Fisher information of a path from n to n+1 is, replacing the continuous differentials with finite differences, and ignoring the expectation operator (which becomes equivalent to the identity operator):

I(n)=2 ln 2(K(Aⁿ⁺¹)−K(Aⁿ))², 0<n<d

The first order bit depth n₀ parameterizing the minimal sufficient statistic Aⁿ^{₀} is the argument n that maximizes the change in complexity, K(Aⁿ⁺¹)−K(Aⁿ):

n₀=arg max I(n), 0<n<d

The first order bit depth of the image channel represented by X_{i,j}^{d} is n₀. That is, the first n₀ most significant bits in each amplitude encode the signal; the remaining bits are noise. The noise floor of the image is n₀.

The second order depth, on the other hand, determines the point of diminishing returns beyond which further description has diminished utility. It is the maximum of the expected Hessian of Hartley information, J(t)ᵢⱼ=E[∂ₜ_{ᵢ}² ln ƒ(X;t)∂ₜ_{ⱼ}² ln ƒ(X;t)], so it becomes:

n_{c}=arg max J(n), 0<n<d

This minimizes K(Aⁿ⁺¹)−2K(Aⁿ)+K(Aⁿ⁻¹). The signal having nₑ bits per sample has the high-value bits and the residual noise function contains the bits determined to have diminishing utility.

When considering multiple channels at once, which allows data compression to utilize correlations between these channels, we simply consider a superset of Aⁿ that is the union of the Aⁿ for each channel Xₖ, where 0≦k<kₘₐₓ. If all the channels have the same bit depth, for instance, this superset becomes:

Aⁿ≡{∪Yᵢⱼ^{m}:Yᵢⱼ^{m}=(Xₖ)ᵢⱼ^{m}, m≦n≦d, 0≦k<kₘₐₓ}

Its corresponding representation is the union of the truncated channels, traditionally, an image would have three of these. Given this new definition, the calculation of first-order depth proceeds as before. Its Fisher information is still I(n)=2 ln 2(K(Aⁿ⁺¹)−K(Aⁿ))², which takes its maximum at the minimal sufficient statistic, the first order depth maximizing K(Aⁿ⁺¹)−K(Aⁿ). The second order depth, as before, maximizes K(Aⁿ⁺¹)−2K(Aⁿ)+K(Aⁿ⁻¹).

It is also possible to take the union of channels having different bit depths. The first-order critical parameters (bit depths) are best determined by the maximum (or a near-maximum) of the Fisher-Rao metric. The second-order critical parameters are determined by the maximum (or a near-maximum) of the Hessian of Hartley information.

If stochastic data is not ergodic, that is, if different regions of data have different statistical properties, these regions may have different critical bit depths. Such data can be compressed by separating regions having different bit depths.

This phenomenon occurs frequently in photographs since brighter regions tend to be encoded using more significant bits, requiring fewer leading bits. Brighter regions thus tend to have lower critical depth than darker regions whose signal is encoded using less significant bits. Darker regions require a greater number of leading bits, but their leading zeros are highly compressible.

The simplest way to accomplish this separation, perhaps, is to divide the original data into rectangular blocks and evaluate each block's critical depth separately. This is suboptimal for a couple of reasons—one, regions of complex data having different bit depths are rarely perfect rectangles; two, normalization or other phenomena can lead to perceptible boundary effects at the junctions of blocks.

For this reason, we develop a means of masking less intense signals for subsequent encoding at a higher bit depth. In this way, the notion of bit depth will be refined—by ignoring leading zeros, the critical bit depth of the data becomes the measure of an optimal number of significant figures (of the binary fraction 2^{-x}=0.x) for sampled amplitudes.

Ideally, we would like to encode the low-amplitude signals at a higher bit depth (given their higher compressibility) while we make a lossy approximation of the Fourier transform of the periodic noise. If a statistical model is available for this approximation, we use this model for the lossy coding, otherwise, a lossy data compression algorithm is employed.

Given the original data, it is easy to distinguish low-amplitude signals from truncated noise—if the original amplitude is greater than the noise floor, a pixel falls into the latter category, otherwise, the former. This allows us to create a binary mask function M^{d} associated with bit depth d, it is 0 if the amplitude of the original data sample exceeds the noise floor, and 1 otherwise:

Mᵢⱼₙ=0 if Aᵢⱼⁿ≧2^{d}; Mᵢⱼⁿ=1 if <2^{d}.

This mask acts like a diagonal matrix that left-multiplies a column vector representation of the image Aᵢⱼ^{d}. The resulting signal Mᵢⱼ^{d}Aᵢⱼ^{d} preserves regions of non-truncated low-intensity signal while zeroing all other amplitudes. Its complement, NOT Mᵢⱼ^{d}= M̅ᵢⱼ^{d} acts on the noise function to preserve regions of periodic truncated noise while zeroing the low-intensity signal. It is also helpful to consider the literal description length of the samples contained in this region, its bit depth times the number of ones appearing in Mⁿ: (d−n) trace(Mⁿ), as well as the complexity of the entire signal, K(Mᵢⱼ^{d}Aᵢⱼ^{d}), which includes the shape of the region, since this is additional information that needs to be represented.

We may now describe an algorithm that calculates critical depths while separating regions of low-intensity signal. This procedure truncates some number (the bit depth) of trailing digits from the original signal, separates truncated regions having only leading zeros, and calculates the complexity of the reduced and masked signal plus the complexity (calculated via recursion) of the excised low-intensity signal at its critical depth. Once this is done, it proceeds to the next bit depth, provided that the maximum depth has not yet been reached.

Starting with shallow representations having only the most significant bits (n=0 or 1, typically), we truncate the data to depth n, resulting in the truncated representation of the signal Aⁿ, as well as its truncated residual (previously ‘noise’) function, which we will call Bⁿ. At this point, the initial truncated signal Aⁿ is compressed using lossless methods, while the mask and its complement are applied to Bⁿ. This results in a residual signal, Sⁿ=MⁿBⁿ=MⁿAᵢⱼ^{d} (for these pixels, Bⁿ agrees with the original data A^{d}) as well as a complementary residual periodic noise function Nⁿ= M̅ⁿBⁿ. Since it contains only residual noise, taken modulo some power of two, the noise Nⁿ is compressed using lossy methods that are typically based on Fourier analysis. The residual signal Sⁿ becomes input for the next iteration.

The procedure iterates using a new Aⁿ⁺¹ that is a truncation of the masked signal Sⁿ, as opposed to the original image. Let the notation Tⁿ represent an operator that truncates amplitudes to bit depth n. In this notation, Aⁿ⁺¹=Tⁿ⁺¹Sⁿ, and its residual function is Bⁿ⁺¹=Aⁿ−Aⁿ⁺¹. A new mask Mⁿ⁺¹ is determined from Aⁿ⁺¹. Using the new mask, we produce a new residual signal, Sⁿ⁺¹=Mⁿ⁺¹Bⁿ⁺¹, and a new residual noise, Nⁿ⁺¹= M̅ⁿ⁺¹Bⁿ⁺¹. Aⁿ⁺¹ is compressed and stored using lossless methods, while Nⁿ⁺¹ is compressed and stored using lossy methods, and the procedure iterates to the next value of n, using Sⁿ⁺¹ as the new signal provided that additional bits exist. If the maximum bit depth has been reached, there can be no further iteration, so Bⁿ is stored using lossy methods.

Though the separation of signal and noise is now iterative, the criterion for critical depth has not changed, only the Aⁿ that appears in their definition. If K(Aⁿ)−K(Aⁿ⁺¹) is nearly maximal−its largest possible value is the literal length, trace(Mⁿ)—the first-order depth has been reached; if K(Aⁿ⁻¹)−2K(Aⁿ)+K(Aⁿ⁺¹) is nearly maximal, the second-order critical depth has been reached. Once the desired depth is reached, the iteration may break, discarding Sⁿ⁺¹ and Nⁿ⁺¹ and storing Bⁿ using lossy methods.

If higher compression ratios are desired, more bits can be truncated and modeled statistically or with lossy methods. However, the signal introduced to the noise function in such a manner might not fit simple statistical models, and the loss of compressible signal tends to interfere with inference.

Since it relates an image's most significant bits to important theoretical notions such as Kolmogorov minimal sufficient statistic and algorithmic entropy, critical bit depth is the canonical example of critical data representation. One could reorder the image data to define a truncated critical scale, simply sampling every nth point, however, this discards significant bits, which tends to introduce aliasing artifacts dependent on the sampling frequency and the frequency of the underlying signal. These considerations are the topic of the celebrated Nyquist-Shannon sampling theorem—essentially, the sampling frequency must be at least twice the highest frequency in the signal. This is known as the Nyquist rate, as it was stated by Nyquist in 1928[11] before filially being proved by Shannon in 1949[14].

As a result of the Nyquist-Shannon theorem, a downsampling operation should incorporate a low-pass filter to remove elements of the signal that would exceed the new Nyquist rate. This should occur prior to the sampling operation in order to satisfy the sampling theorem. To complicate matters further, idealized filters can't be attained in practice, and a real filter will lose some amount of energy due to the leakage of high frequencies. A low-pass filter based on a discrete Fourier transform will exhibit more high-frequency leakage than one based on, for example, polyphase filters. Since sampling is not the topic of this paper, we will simply refer to an idealized sampling operator B that applies the appropriate low-pass filters to resample data in one or more dimensions.

The ability to perform complexity-based inference on a common scale is important since it allows the identification of similar objects, for instance, at different levels of magnification. Critical scale is useful as it provides another degree of freedom along which critical points may be optimized, analogous to phase transitions in matter that depend on both temperature and pressure. Occasionally, the two objectives may be optimized simultaneously at a ‘triple point’ that is critical for both bit depth and scale.

We now define the critical scale, which we define in terms of operators which resample the image instead of truncating it. For some data, a minimal sufficient statistic for scale cannot be reliably selected or interpreted, and hence a critical scale can't be determined.

Consider the critical scale of an image at a particular bit depth d, which may or may not be the original bit depth of the image. Let the linear operator B_{r,s} represent a resampling operation, as described above, applied to an image with a spatial period of r in the x dimension and a period of s in the y dimension. It's action on X_{i,j}^{d} is a i/r by j/s matrix of resampled amplitudes.

This operator gives us two possible approaches to scaling. On one hand, given divisibility of the appropriate dimensions, we may vary r and s to resample the image linearly. On the other hand, we may also apply the operator repeatedly to resample the image geometrically, given divisibility of the dimensions by powers or r and s. The former may identify the scale of vertical and horizontal components separately, and the latter identifies the overall scale of the image. We will consider first overall scale, using the iterated operator, and then the horizontal and vertical components.

B_{r,s}ⁿ, then, is the result of applying this operator n times. Let the set used by the structure function, Aⁿ, contain all the images whose m leading bits agree with those of B_{r,s}ⁿX_{i,j}^{d}:

Aⁿ≡{Yᵢⱼ^{m}:Yᵢⱼ^{m}=B_{r,s}ⁿXᵢⱼ^{m}, m≦d}

Note that in this case, unlike the critical bit depth, Aⁿ is an averaging which is not necessarily a prefix of the original image. The original image has ijd bits. The reduced image has

$$\frac{dij}{{( rs )}^{n}}$$

bits. We may now write the first-order critical scale n₀ parameterizing the minimal sufficient statistic Aⁿ^{₀}, an expression unchanged from the previous case:

n₁=arg max I(n)=arg max 2 ln 2(K(Aⁿ⁺¹)−K(Aⁿ))², 0<n<d

If higher compression ratios are needed, additional signal may be discarded, as described previously. The expression for the second-order critical scale is also unchanged:

n₂=arg max J(n)=arg max K(Aⁿ⁺¹)−2K(Aⁿ)+K(Aⁿ⁻¹), 0<n<d

As mentioned previously, the repeated application of averaging operators is not always appropriate or possible. We will consider linear scaling parameterized along the horizontal axis, with the understanding that the same operations may be applied to the vertical axis, or to any other index. As such, we equate the parameter n with the horizontal factor r. The set Aⁿ then contain all the images whose m leading bits agree with those of B_{n,s}X_{i,j}^{d}:

Aⁿ≡{Yᵢⱼ^{m:Y}ᵢⱼ^{m}=B_{n,s}Xᵢⱼ^{m}, m≦d}

Note that this set may not be defined for all n. Given this set, the expressions for the maximum Fisher information (the minimal sufficient statistic) and the maximum of the Hessian of Hartley information (the critical point) do not change.

If a signal is to compressed at some scale other than its original scale, then it will need to be resampled to its original scale before being added to its decompressed (lossy) noise function. Note than in this case, the resampled signal is not generally lossless. This smoothing of data may be acceptable, however, since it enables analysis at a common scale.

We now consider critical bit depths and scales of multidimensional data. Instead of a two dimensional array containing the amplitudes of an image, we consider an array with an arbitrary number of dimensions. As noted earlier, monophonic audio may be represented as a one dimensional array of scalar amplitudes, and video data may be represented as a three dimensional array which also has three channels. This generalizes the results of the previous two sections, which used the case of a two-dimensional image for illustrative purposes.

Let Xₐ_{₀}_{. . . a}_{_{m−1}}^{d}^{₀}^{. . . d}^{ᵥ} represent a tensor of rank m+v. Its subscripts index coordinates in an m-index array whose values are v-dimensional vectors. Each vector component is a dᵢ-bit number. The superscripts index the bits in these numbers, ordered from most significant to least significant. We will first determine its critical bit depths and then its critical scales.

Let the set Aⁿ^{₀}^{. . . n}^{ᵥ} contain all possible tensors Yₐ_{₀}_{. . . a}_{_{m−1}}^{d} whose nᵢ leading bits agree with those of channel i in the original tensor Xₐ_{₀}_{. . . a}_{_{m−1}}^{d}^{₀}^{. . . d}^{ᵥ}:

Aⁿ^{₀}^{. . . n}^{ᵥ}≡{Yₐ_{₀}_{. . . a}_{_{m−1}}^{b}^{₀}^{. . . b}^{_{m−1}}:Yₐ_{₀}_{. . . a}_{_{m−1}}^{b}^{₀}^{. . . b}^{_{m−1}}=Xₐ_{₀}_{. . . a}_{_{m−1}}^{b}^{₀}^{. . . b}^{_{m−1}}, bᵢ≦nᵢ≦dᵢ}

Since there are multiple parameters involved in determining the first-order bit depth, a general tensor requires the use of the full Fisher-Rao metric, rather than the Fisher information:

I(n₀ . . . nᵥ)ᵢⱼ˜(K(Aⁿ^{₀}^{. . . n}^{ᵢ₊₁}^{. . . n}^{ᵥ})−K(Aⁿ^{₀}^{. . . n}^{ᵢ}^{. . . n}^{ᵥ}))(K(Aⁿ^{₀}^{. . . n}^{ⱼ₊₁}^{. . . n}^{ᵥ})−K(Aⁿ^{₀}^{. . . n}^{ⱼ}^{. . . n}^{ᵥ}))

Where the expectation value in the definition of I(t) becomes the identity, as before. For any particular parameter nₖ, I(t) takes on a maximum with respect to some value that parameter. This value is the critical depth of channel k. However, this does not necessarily indicate that the set of critical depths globally maximizes I(t). The global maximum occurs at some vector of parameter values \vec{n}=(n₀, . . . , nᵥ):

\vec{n}₁=arg max I(n₀ . . . nᵥ)ᵢⱼ, 0<nᵢ<d

If channels having different depths are inconvenient, a single depth may be selected as before, using the one-parameter Fisher information of P(X)=2^{-K(X)}:

n₁=arg max I(n)ᵢⱼ=arg max 2 ln 2(K(Aⁿ⁺¹)−K(Aⁿ))², 0<n<d

The second-order critical depth proceeds in a similar manner. The expected Hessian of Hartley information J(\vec{n})ᵢⱼ becomes 2 ln 2 times

(K(A^{. . . n}^{ᵢ₊₁}^{. . .} )−2K(A^{. . . n}^{ᵢ}^{. . .} )+K(A^{. . . n}^{_{i−1}}^{. . .} ))(K(A^{. . . n}^{ⱼ₊₁}^{. . .} )−2K(A^{. . . n}^{ⱼ}^{. . .} )+K(A^{. . . n}^{_{j−1}}^{. . .} ))

Again, the maximum occurs at a vector of parameter values \vec{n}_{c}=(n₀, . . . , nᵥ):

\vec{n}₂=arg max J(n₀ . . . nᵥ)ᵢⱼ, 0<nᵢ<d

We will now consider the critical scale of Xₐ_{₀}_{. . . a}_{_{m−1}}^{d}^{₀}^{. . . d}^{ᵥ}. Let the linear operator Bᵢ_{₀}_{. . . i}_{_{m−1}} represent an idealized resampling of the tensor by a factor of iₖ along each dimension k. This operator applies a low-pass filter to eliminate frequency components that would exceed twice the new sampling frequency (the Nyquist rate

$$\frac{2}{{i}_{k}}$$

) prior to sampling with frequency

$$\frac{1}{{i}_{k}} .$$

Let the set used by the structure function, Aⁿ^{₀}^{. . . n}^{ᵥ}, contain all the tensors which are preimages of Bᵢ_{₀}_{. . . i}_{_{m−1}}X_{i,j}^{d}, the rescaled tensor:

Aⁿ^{₀}^{. . . n}^{ᵥ}≡{Yₐ_{₀}_{. . . a}_{_{m−1}}^{b}^{₀}^{. . . b}^{_{m−1}}:Yₐ_{₀}_{. . . a}_{_{m−1}}^{b}^{₀}^{. . . b}^{_{m−1}}=Bᵢ_{₀}_{. . . i}_{_{m−1}}ⁿXₐ_{₀}_{. . . a}_{_{m−1}}^{b}^{₀}^{. . . b}^{_{m−1}}, m≦n≦d}

Given this new definition of A, the definition of first and second order critical depth do not change. The first-order critical scales maximize (or approximately maximize) the Fisher information:

\vec{n}=arg max I(n₀ . . . nᵥ)ᵢⱼ

Likewise, the second-order critical scales maximize the expected Hessian of Hartley information:

\vec{n}=arg max J(n₀ . . . nᵥ)ᵢⱼ

Alternately, a single scale parameter could be chosen in each case:

n₁=arg max I(n . . . n)ᵢⱼ=arg max K(Aⁿ⁺¹)−K(Aⁿ), 0<n<d

n₂=arg max J(n . . . n)ᵢⱼ=arg max K(Aⁿ⁺¹)−2K(Aⁿ)+K(Aⁿ⁺¹), 0<n<d

Hence, we see that the definition of first and second order critical scale of a general tensor is identical to their definition for rank two images.

The above relations are idealized, assuming that K can be evaluated using perfect data compression. Since this is not generally the case in practice, as discussed previously, the maxima of I and J may be discounted by some tolerance factor to produce the threshold of a set of effectively maximal parameter values. The maximum or minimum values within this set may be chosen as critical parameters.

In addition to multimedia data such as audio (m=1), images (m=2), and video (m=3), these relations enable critical compression and decompression, pattern recognition, and forecasting for many types of data.

We now have an approach to separate significant signals from noise. Encoding the resulting signal follows traditional information theory and lossless compression algorithms. Encoding the noise is a separate problem of statistical inference that could assume several variants depending on the type of data involved as well as its observer. Regardless of the details of the implementation, the program is as follows: a statistical model is fit to the noise, its parameters are compressed and stored, and upon decompression, a sample is taken from the model.

A lossless data compression scheme must encode both a signal and its associated noise. However, noise is presumed ergodic and hence no more likely or representative than any other noise sampled from the same probability distribution. Hence, a ‘lossy’ perceptual code is free to encode a statistical model (presuming that one exists) for the noisy bits, as their particular values don't matter. This dramatically reduces the complexity of storing incompressible noise; its effective compression ratio may approach 100% by encoding relatively simple statistical models. The most significant bits of the signal are compressed using a lossless entropic code; when the image is decompressed, samples are taken from the model distribution to produce an equivalent instance of noise; this sampled noise is then added to the signal to produce an equivalent image.

As noted in the introduction, maximum likelihood estimates correspond to sufficient statistics[4]. Maximum likelihood estimation (MLE) has been one of the most celebrated approaches to statistical inference in recent years. There are a wide variety of probability distribution functions and stochastic processes to fit to data, and many specialized algorithms have been developed to optimize the likelihood. A full discussion of MLE is beyond the scope of this paper, but the basic idea is quite simple. Having computed a minimal sufficient statistic, we wish to fit a statistical model having some finite number of parameters (such as moments of the distribution) to the noisy data. The parameter values leading to the most probable data are selected to produce the most likely noise model. Our data compression scheme stores these parameter values, compressed losslessly if their length is significant, in order to sample from the statistical model when decompression occurs.

Since different regions of data may have different statistical properties, rather than fitting a complex model to the entire noisy string, it may be advantageous to fit simpler models to localized regions of data. The description length of optimal parameters tends to be proportional to the number of parameters stored. If a model contains too many parameters, the size of their representation can approach the size of the literal noise function, reducing the advantage of critical compression.

When the image is decompressed, a sample is drawn from the statistical model stored earlier. The problem of sampling has also received considerable attention in recent years, due to its importance to so-called Monte Carlo methods. The original Monte Carlo problem, first solved by Metropolis and Hastings, dealt with the estimation of numerical integrals via sampling. Since then, Monte Carlo has become somewhat of a colloquial term, frequently referring to any algorithm that samples from a distribution. Due to the importance of obtaining a random sample in such algorithms, Monte Carlo sampling has become a relatively developed field. Box-Muller is a simple option for sampling from the uniform distibution[8], which may be transformed into any other distribution with a known cumulative distribution function. The Ziggurat algorithm[10] is a popular sampling algorithm for arbitrary distributions. This algorithm provides reasonably high-performance sampling since the sequence of samples produced is known to repeat only after a very large number of iterations.

Psychological modeling should be incorporated into the statistical models of the noise component rather than the signal, since this is where the ‘loss’ occurs in the compression algorithm. The information loss of the noise component (as well as its low perceptibility) also lends itself directly to applications such as steganography and watermarking. Since noise can't be learned efficiently, different instances of noise from the same ergodic source will typically appear indistinguishable to a macroscopic observer who makes statistical inferences. Furthermore, certain distinct ergodic sources will appear indistinguishable. A good psychological model will contain parameters relevant to the perception of the observer and allow irrelevant quantities to vary freely. It may be advantageous to transform the noisy data to an orthogonal basis, for example, Fourier amplitudes, and fit parameters to a model using this basis. The particular model used will depend on the type of data being observed and, ultimately, the nature of the observer. For example, a psychoacoustic model might describe only noise having certain frequency characteristics. The lossy nature of the noise function also provides a medium for other applications, such as watermarking.

Maximum likelihood estimation applies only when an analytic model of noise is available. In the absence of a model, the noise function may be compressed using lossy methods, as described previously, and added to the decompressed signal to reconstruct the original datum.

The most obvious obstacle to this procedure is the fact that lossy data compression algorithms do not necessarily respect the intensity levels present in an image. For example, high levels of JPEG compression produces blocking artifacts resembling the basis functions of its underlying discrete cosine transformation. Fitting these functions to data may result in spurious minima and maxima, often at the edges or corners of blocks, which frequently exceeds the maximum intensity of the original noise function by nearly a factor of two. With the wavelet transforms used in JPEG2000[1], the spurious artifacts are greatly diminished compared to the discrete cosine transforms of the original JPEG standard, but still present, so a direct summation will potentially exceed the ceiling value allowed by the image's bit depth.

In order to use the lossy representation, the spurious extrema must be avoided. It is not appropriate to simply truncate the lossy representation at the noise floor, as this leads to ‘clipping’ effects—false regularities in the noise function that take the form of artificial plateaus. Directly normalizing the noise function does not perform well, either, as globally scaling intensities below the noise floor leads to an overall dimming of the noise function relative to the reconstructed signal. A better solution is to upsample the noise function, normalizing it to the maximum amplitude, and storing the maximum and minimum intensities of the uncompressed noise. Upon decompression, the noise function image is ‘de-normalized’ (downsampled) to its original maximum and minimum intensities before being summed with the signal. This process preserves the relative intensities between the signal and noise components.

Therefore, when constructing codes with both lossless and lossy components, a normalized (upsampled) noise function is compressed with lossy methods, encoded along with its original bit depth. Upon decompression, the noise function is decompressed and re-normalized (downsampled) back to its original bit depth before being added to the decompressed signal.

Last, but not least, it is worth noting that separating a signal from noise generally improves machine learning and pattern recognition. This is especially true in compression-based inference. Complexity theory provides a unified framework for inference problems in artificial intelligence[9], that is, data compression and machine learning are essentially the same problem[3] of knowledge representation.

These sorts of considerations have been fundamental to information theory since its inception. In recent years, compression-based inference experienced a revival following Rissanen's 1986 formalization[9] of minimal description length (MDL) inference. Though true Kolmogorov complexities (or algorithmic prefix complexities) can't be calculated in any provable manner, the length of a string after entropic compression has been demonstrated as a proxy sufficient for statistical inference. Today, data compression is the central component of many working data mining systems. Though it has historically been used to increase effective network bandwidth, data compression hardware has improved in recent years to meet the high-throughput needs of data mining. Hardware solutions capable of 1 gbps or more of Lempel-Ziv compression throughput can be implemented using today's FPGA architectures. In spite of its utility in text analysis, compression-based inference remains largely restricted to highly compressible data such as text. The noise intrinsic to stochastic real-world sources is, by definition, incompressible, and this tends to confound compression-based inference.

Essentially, incompressible data is non-learnable data[9]; removing this data can improve inference beyond the information-theoretic limits associated with the original string. By isolating the compressible signal from its associated noise, we have removed the obstacle to inference using the complexity of stochastic data. Given improved compressibility, the standard methods of complexity-based inference and minimum description length may be applied to greater effect.

By comparing the compressibility of signal components to the compressibility of their concatenations, we may identify commonalities between signals. A full treatment of complexity-based inference is beyond the scope of this paper (the reader is referred to the literature, particularly the book by Li and Vitányi[9]) but we reproduce for completeness some useful definitions. Given signal components A and B, and their concatenation AB, we may define the conditional prefix complexity K(A|B)=K(AB)−K(B). This quantity is analogous to the Kullback-Leibler divergence or relative entropy, and this allows us to measure a (non-symmetric) distance between two strings.

Closely related to the problem of inference is the problem of induction or forecasting addressed by Solomonoff[9]. Briefly, if the complexity is K(x), then the universal prior probability M(x) is typically dominated by the shortest program, implying M(x)≈2^{-K(x)}. If x is, for example, a time series, then the relative frequency of two subsequent values may be expressed as a ratio of their universal probabilities. For example, the relative probability that the next bit is a 1 rather than 0 is

$$P = \frac{M ( x 1 )}{M ( x 0 ) \approx {2}^{K ( x 0 ) - K ( x 1 )}} .$$

Clearly, the evaluation of universal probabilities is crucially dependent on compressibility. As such, separating signal from noise in the manner described also improves the forecasting of stochastic time series.

Sometimes, one wishes to consider not only the complexity of transforming A to B, but also the difficulty of transforming B to A. In the example presented, an image search algorithm, this is not the case—the asymmetric distances produce better and more intuitive results. However, if one wishes to consider the symmetrized distances, the most obvious might be symmetrized sum of conditional complexities K(A|B) and K(B|A), D(A,B)=K(AB)+K(BA)−K(A)−K(B). This averaging loses useful information, though, and many authors[9] suggest using the ‘max-distance’ or ‘picture distance’ D(A,B)=max{K(A|B),K(B|A)}=max{K(AB)−K(B),K(BA)−K(A)}. When implementing information measures, the desire for the mathematical convenience of symmetric distance functions should be carefully checked against the nature of the application. For example, scrambling an egg requires significantly fewer interactions than unscrambling and subsequently reassembling that egg, and a reasonable complexity measure should reflect this. For these considerations, as well as its many convenient mathematical properties[9] the conditional prefix complexity is often the best measure of the similarity or difference of compressible signals. Empirical evidence suggests that conditional prefix complexity outperforms either the symmetrized mutual information or the max-distance for machine vision. The reverse transformation should not usually be considered since this tends to overweight low-complexity signals.

We will demonstrate an example sliding-window algorithm which calculates conditional prefix complexities K(A|B) between a search texture, A, and elements B from a search space. The measure K(A|B)=K(AB)−K(B) is closely related to the universal log-probability that A will occur in a sequence given that B has already been observed. Its minimum is the most similar search element. It is invariant with respect to the size of elements in the search space and does not need to be normalized. Estimating the complexities of signal components from the search space and the complexities of their concatenations with signal components from the texture, we arrive at an estimate of K(A|B) which may be effectively utilized in a wide variety of artificial intelligence applications.

The first-order critical point represents the level at which all the useful information is present in a signal. At this point, the transition from order to chaos is essentially complete. For the purposes of artificial intelligence, we want enough redundancy to facilitate compression-based inference, but alto to retain enough specific detail to differentiate between objects. The second-order critical point targets the middle of the phase transition between order and chaos, where the transition is proceeding most rapidly and both of these objectives can be met. In the examples section, we will see that visual inference at the second-order critical depth outperforms inference at other depths. For this reason, second-order critically compressed representations perform well in artificial intelligence applications.

### Advantageous Effects of Invention

A critical depth (or other parameter, such as scale) represents ‘critical’ data in two senses of the word: on one hand, it measures the critical point of a phase transition between noise and smoothness, on the other, it also quantifies the essential information content of noisy data. Such a point separates lossless signals from residual noise, which is compressed using lossy methods.

The basic theory of using such critical points to compress numeric data has now been developed. This theory applies to arrays of any dimension, so it applies to audio, video, and images, as well as many other types of data. Furthermore, we have demonstrated that this hybridization of lossless and lossy coding produces competitive compression performance for all types of image data tested. Whereas lossy transformation standards such as JPEG2000 sometimes include options for separate lossless coding modes, a two-part code adapts to the data and smoothly transitions between the two types of codes. Such two-part codes are somewhat unique in being efficient for compressing both low-entropy and high-entropy sources.

The optional integration of Maximum Likelihood models and Monte-Carlo-type sampling is a significant departure from deterministic: algorithms for data compression and decompression. If sampling is employed, the decompression algorithm becomes stochastic and nondeterministic, potentially producing a different result each time decompression occurs. The integration of statistical modeling into such an algorithm enables two-part codes which are engineered for specific applications. This can lead to much higher levels of application-specific compression than can be achieved using general-purpose compression, as has been illustrated using a simple image corrupted by noise.

The test images presented use a bit depth of 8 bits per channel, as is standard in most of today's consumer display technology. However, having more bits per sample (as in the proposed HDR image standard, for instance) means that the most significant bits represent a smaller fraction of the total data. As such, the utility of a two-part code is increased at the higher bit depth, since more of the less-significant bits can be highly compressed using a lossy code, while the significant bits still use lossless compression.

Likewise, high-contrast applications will benefit from the edge-preserving nature of a two-part code. Frequency-based methods suffer from the Gibbs' phenomenon, or ‘ringing,’ which tends to blur high-contrast edges. In the approach described, this phenomenon is mitigated by limited use of such methods. A two-part code should perform well in applications in which the fidelity of high-contrast regions is important.

As suggested previously, a two-part code can significantly outperform lossy transforms by many orders of magnitude for computer-generated artwork, cartoons, and most types of animation. The low algorithmic complexity intrinsic to such sources leads to efficiently coded signals.

In most test cases, critical compression also outperforms JPEG2000 by orders of magnitude for black-and-white images. Without the advantage of separating color data into chrominance subspaces, the prevailing lossy compression algorithms seem much less efficient. For this reason, two-part codes seem to outperform JPEG coding alone in many monochrome applications.

JPEG2000 does perform well for its intended purpose—generating a highly compressed representation of color photographs. For most of the color test photographs, a two-part code overtakes JPEG2000 at high quality levels. The point at which this occurs (if it does) varies by photograph. At relatively low bitrates, JPEG2000 usually outperforms a two-part code, but usually by less than an order of magnitude. All examples presented to this point were directly coded in the RGB color space. Since the theory of two-part codes applies to any array of n-bit integers, we could have just as easily performed analysis in the YC_{b}Cᵣ color space, like the JPEG algorithms, which often improves the redundancy apparent in color data.

One unique aspect of the hybridization of lossless and lossy data compression is its ability to code efficiently over a wide variety of data. It can efficiently code both algorithmically generated regular signals (such as computer generated graphics or animation) and stochastic signals from empirical data (such as photographs). The former tends to be periodic, and the random aspects of the latter tend to exhibit varying degrees of quasiperiodicity or chaos. However, the creation of periodicity or redundancy is essential to the comparison operation—the prefix complexity involves concatenation, which is similar to repetition if the concatenated objects are similar. Concatenation can create periodicity from similarities, even if the objects being concatenated have no significant periodicity within themselves, as may be the case with data altered by noise. The inferential power of critical compression derives from its ability to compress redundancy which would otherwise be obscured by noise.

In spite of its ultimately incalculable theoretical underpinnings, the human eye intuitively recognizes a critical bit depth from a set of truncated images. The mind's eye intuitively recognizes the difference between noisy, photographic, “real world” signals and smooth, cartoon-like, artificial ones. Human visual intelligence can also identify the effective depth from the noisy bits—it is the depth beyond which features of the original image can be discerned in the noise function. Conversely, given a computer to calculate the critical point of an image, we can determine its critical information content. Since noise can't be coded efficiently due to its entropy, an effective learner, human or otherwise, will tend to preferentially encode the critical content. This leads directly to more robust artificial intelligence systems which encode complex signals in a manner more appropriate for learning.

### BRIEF DESCRIPTION OF DRAWINGS

The patent or application file contains at least one drawing executed in color. Copies of this patent or patent application publication with color drawing(s) will be provided by the Office upon request and payment of the necessary fee.

FIG. 1 Nine images of a dark gray box on a light gray background representing the signal at bit depths of 0 through 8. The image at the upper left has all 8 bits, and the solid black image at the lower right represents the absence of any signal. Note that depth 3, at middle right, is undergoing a phase transition between the previous five noisy images and the next three smooth images. This is the second-order critical depth, the point of diminishing representational utility.

FIG. 2 Nine images representing the noise extracted from the signals illustrated in FIG. 1. The First-order critical depth is depth 3, so the full noise function may be viewed at middle right. It is clear that beyond this second order critical depth, the signal of the image creeps back into the noise function in the lower row.

FIG. 3 The second-order critically compressed image (13776 bits), at top left, adjacent to the uncompressed original image (524288 bits), at top right, for comparison. The two images are practically indistinguishable to the naked eye. Below, a JPEG compressed image (104704 bits) is displayed for comparison purposes. In addition to being almost eight times the size of the critically compressed image, correlations in the form of blurring are visible in the JPEG-compressed noise, resulting in a less crisp textural appearance and biased statistical properties.

FIG. 4 A signal derived from three independent channels of a color photograph and truncated at depth n=8, which is identical to the original image.

FIG. 5 A signal derived from three independent channels of a color photograph and truncated at depth n=7.

FIG. 6 A signal derived from three independent channels of a color photograph and truncated at depth n=6.

FIG. 7 A signal derived from three independent channels of a color photograph and truncated at depth n=5.

FIG. 8 A signal derived from three independent channels of a color photograph and truncated at depth n=4. In this case, the first-order critical depth of the green channel is 4.

FIG. 9 A signal derived from three independent channels of a color photograph and truncated at depth n=3. The first-order depth of the red and blue channels are 3, note that the critical depth separates complex, noisy patterns from simple, cartoon-like ones.

FIG. 10 A signal derived from three independent channels of a color photograph and truncated at depth n=2.

FIG. 11 A signal derived from three independent channels of a color photograph and truncated at depth n=1.

FIG. 12 The noise truncated from FIG. 4, normalized to 100 percent intensity, resulting in a solid white image.

FIG. 13 The noise truncated from FIG. 5, normalized to 100 percent intensity for easier viewing.

FIG. 14 The noise truncated from FIG. 6, normalized to 100 percent intensity for easier viewing.

FIG. 15 The noise truncated from FIG. 7, normalized to 100 percent intensity for easier viewing.

FIG. 16 The noise truncated from FIG. 8, normalized to 100 percent intensity for easier viewing. Beyond this first-order critical depth of 4, signal features such as the outlines of trees and clouds creep back into the image, starting with shadows and other darkened regions, suggesting that the bit depth of these regions differs from that of the image as a whole. The bright blue sky is also at a different bit depth from the overall image, and it is also worth noting that even relatively insignificant bits (n=4 and n=5) retain certain signals. Due to this sort of inhomogeneity, some cases and applications may benefit from dividing data into blocks (or more generalized regions) and evaluating their critical depth/scale separately.

FIG. 17 The noise truncated from FIG. 9, normalized to 100 percent intensity for easier viewing.

FIG. 18 The noise truncated from FIG. 10, normalized to 100 percent intensity for easier viewing.

FIG. 19 The noise truncated from FIG. 11, normalized to 100 percent intensity for easier viewing.

FIG. 20 The critically compressed and decompressed image.

FIG. 21 Improved data compression leads to a better estimate of the second-order critical depth and a more economical representation. The second order critically compressed and decompressed image (at depth 3) is shown here.

FIG. 22 Pattern search at depth 1.

FIG. 23 Pattern search at depth 2.

FIG. 24 Pattern search at depth 3.

FIG. 25 Pattern search at depth 4. Depth 4 has fewer false positives than other depths as its greater economy translates into superior inference. At lower depths, more false matches occur, since more of the image looks similar at this depth. The full image at depth 8 has strong false matches and inferior performance (See FIG. 29) even though it contains all available information, giving too much weight to bits which do not contain useful information about the signal. This tends to overweight, for instance, short and possibly irrelevant literal matches. Signals at depths 5-8 (see FIGS. 26-28) also exhibit this phenomenon to a lesser extent.

FIG. 26 Pattern search at depth 5.

FIG. 27 Pattern search at depth 6.

FIG. 28 Pattern search at depth 7.

FIG. 29 Pattern search at depth 8.

FIG. 30 JPEG2000 compressed version of the fireworks image.

FIG. 31 The luminance channel of the fireworks image, truncated to a bit depth of 4 and losslessly compressed.

FIG. 32 The original version of the fireworks image.

FIG. 33 The decompressed image which results from using FIG. 31 to establish absolute bounds which constrain the luminance values predicted by the lossy coding of FIG. 30.

### DESCRIPTION OF EMBODIMENTS

Having described the method, we now apply it to some illustrative examples. We will start with trivial models and household data compression algorithms, proceeding to more sophisticated implementations that demonstrate the method's power and utility. These examples should be regarded as illustrations of a few of the many possible ways to implement and utilize two-part codes, rather than specific limitations of this method.

One caveat to the application of complexity estimates is the fact that real-world data compression produces finite sizes for strings which contain no data, as a result of file headers, etc. We will treat these headers as part of the complexity of compressed representations when the objective of the compression is data compression, as they are needed to reconstruct the data. When calculating derivatives of complexity to determine critical points, this complexity constant does not affect the result, as the derivative of a constant is zero. It does not affect the conditional prefix complexity, either, canceled by taking a difference of complexities.

For certain applications in artificial intelligence, however, small fluctuations in complexity estimates can lead to large difference in estimates of probabilities. When the quality of complexity estimates are important, as is the case for inference problems, we will first compress empty data to determine the additive constant associated with the compression overhead, and this complexity constant is subtracted from each estimate of K(X). Formally, the data compression algorithm is regarded as a computer and its overhead is absorbed into this computer's Turing equivalence constant. This results in more useful estimates of complexity which improves our ability to resolve low-complexity objects under certain complexity measures.

First-order critical data compression represents a level of detail at which a signal is essentially indistinguishable from an original when viewed at a macroscopic scale. We will show that second-order critical data compression produces representations which are typically slightly more lossy but significantly more compact. As mentioned earlier, any depth could potentially be used, splitting a two-part code subject to the constraints of the intended application.

### EXAMPLES

Since images may be represented in print more readily than video or audio, we will consider image compression here, with the understanding that the data being compressed could have an arbitrary dimensionality and number of channels, as described previously. Example 1 will consider representing an image as the sum of a losslessly compressed signal and its lossy-compressed error function. Example 2 considers the use of the signal component for inference, specifically, it is demonstrated that a bit depth resulting in superior compressibility also results in superior description-length based inference. In Example 3, a simpler and more general approach represents an image as a lossy-compressed version of the original image whose intensity values are corrected using absolute upper and lower bounds which are obtained from a losslessly compressed image at a lower bit depth.

### Example 1

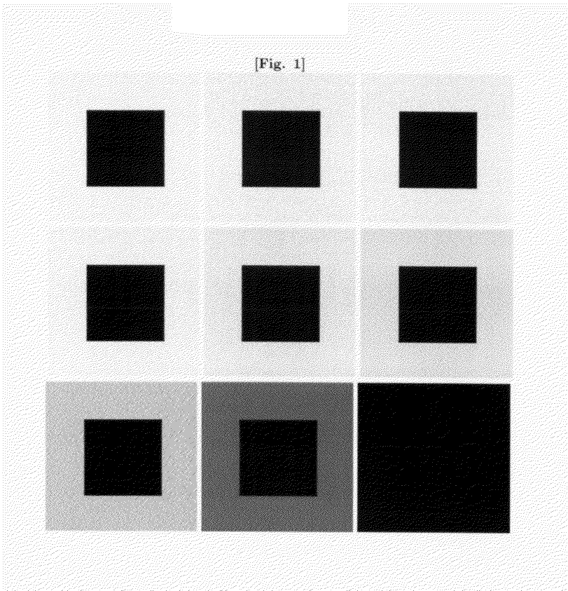

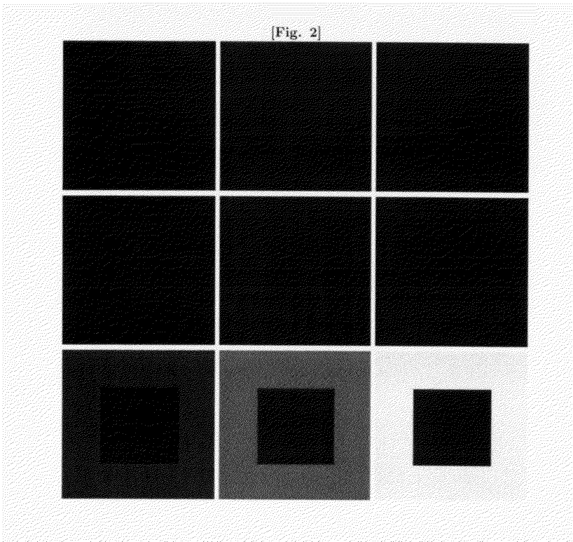

First, consider the second-order critical depth of a simple geometric image with superimposed noise. This is a 256×256 pixel grayscale image whose pixels have a bit depth of 8. The signal consists of a 128×128 pixel square having intensity 15 which is centered on a background of intensity 239. To this signal we add, pixel by pixel, a noise function whose intensity is one of 32 values uniformly sampled between −15 and +16. Starting from this image, we take the n most significant bits of each pixel's amplitude to produce the images Aⁿ, where n runs from 0 to the bit depth, 8. These images are visible in FIG. 1, and the noise functions that have been truncated from these images are showcased in FIG. 2.

To estimate K(Aⁿ), which is needed to evaluate critical depth, we will compress the signal Aⁿ using the fast and popular gzip compression algorithm and compress its residual noise function into the ubiquitous JPEG format. We will then progress to more accurate estimates using slower but more powerful compression algorithms, namely, PAQ8 and JPEG2000. The results for n=0 through 9 are 0, 1584, 2176, 13760, 129200, 282368, 441888, 659296, 735520. This is the size of gzip's representation, which is used as an estimate (an upper bound) of K(Aⁿ).

The most significant bits enjoy higher compression ratios than the noisy bits. In addition to the relative smoothness of many interesting data, there are fundamental reasons (such as Benford's law and the law of large numbers) why leading digits should be more compressible. To estimate the Kolmogorov sufficient statistic, we would to compress the original image in the order of the bits' significance until compressing an additional bit of depth increases the size of the representation just as much as storing that additional bit of depth without compression. If the data compression algorithm doesn't see the image as being random (which is not the case here) we would store bits until adding an additional bit increases the representation by a maximal or nearly maximal amount.

A single image channel is second-order critical at depth n when K(Aⁿ⁺¹)−2K(Aⁿ)+K(Aⁿ⁻¹) is within some tolerance factor of its maximal value. We select a 25 percent tolerance factor, chosen somewhat arbitrarily based on the typical magnitude of complexity fluctuations. The depth n among this maximal set which has the minimum complexity K(Aⁿ) is selected as the critical point. For the given data, we see that no other second difference is within 25% of the maximum, n=3. The first-order critical point, on the other hand, doesn't occur until the phase transition is estimated to be complete at n=7. [FIG. 1]

Having compressed the critical signal data, we may now fit a statistical model to the residual noise function, which may be seen in FIG. 2. We will assume noise whose intensity function is discrete and uniformly distributed, as should be the case. We use maximum likelihood estimation to determine the parameters, which are simply its minimum and maximum values. [FIG. 2]

If the maximum and minimum values of the uniform discrete distribution are a and b, the likelihood of intensity i in any particular pixel is

$$\frac{1}{b - a}$$

if a≦i≦b and zero otherwise. We assume pixels are independent, so the likelihood of any particular noise pattern is simply the product of the likelihoods of each pixel's noise.

To use maximum likelihood estimation, we vary a and b in order to determine which of their values leads to the maximum likelihood. In practice, this can lead to very small numbers that suffer from floating-point errors, so it is customary to maximize the logarithm of likelihood, which is equivalent since the logarithm function is convex. The log-likelihood is simply a b if a≦i≦b and infinity otherwise. This is summed over all 65536 pixels in the noise function and maximized. The first-order critical depth is 3, so the bit depth of the noise function is 5, meaning that the noise can potentially take on one of 2⁵=32 values. For brevity of presentation, we optimize by brute force, calculating noise function likelihoods for all possible a and b such that −16≦b<a≦16. Executing this procedure, we see it recovers the correct set of parameters: a=0, b=31. Note that this distribution has the same variance but a different mean from the noise generated for the test image. A more appropriate optimization algorithm should have faster performance but the same result.

We have succeeded in applying second-order critical compression to the image. We store 13760 bits of compressed signal, corresponding to the second-order critical depth of 3, and 8 bits for each of the parameters a and b calculated above. The compressed representation has 13776 bits, whereas the original image has 524288 bits. Second-order critical compression attains a compression ratio of 38:1 or 97.4%, and, as the reader may verify, the result is very difficult for the human eye to distinguish from the original image (try looking at the corner pixels) without a magnifying device. For this reason, these images are referred to as being macroscopically equivalent; they are both microstates of the same macrostate. [FIG. 3]

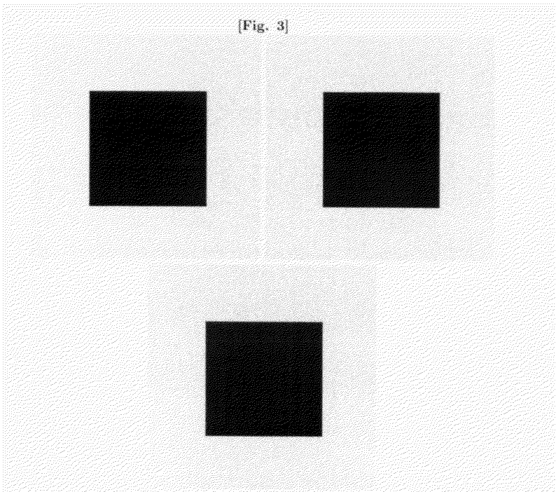

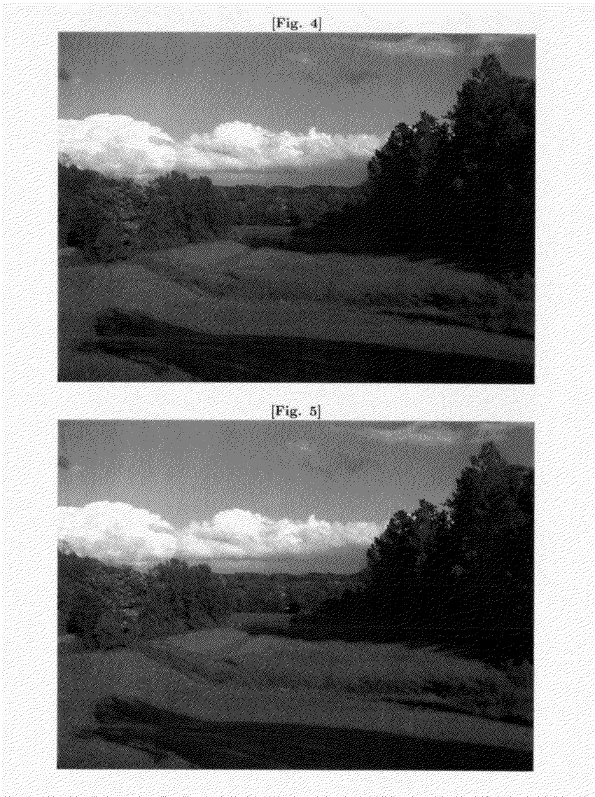

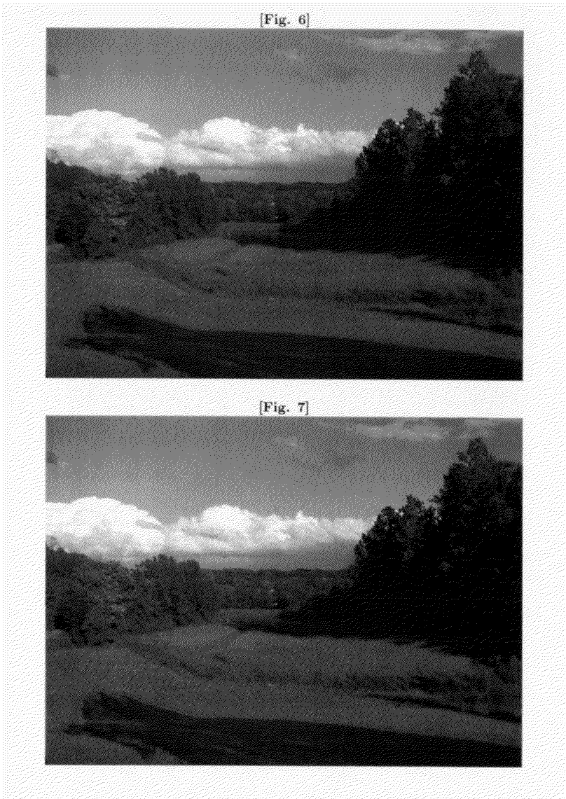

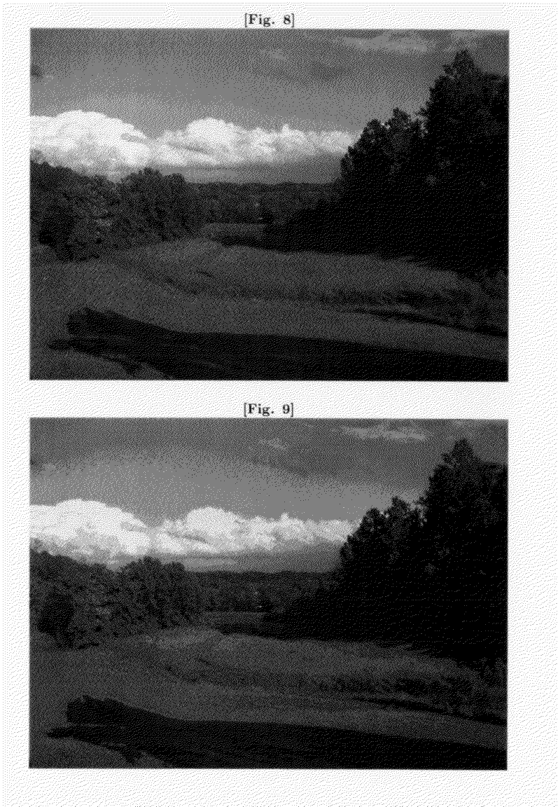

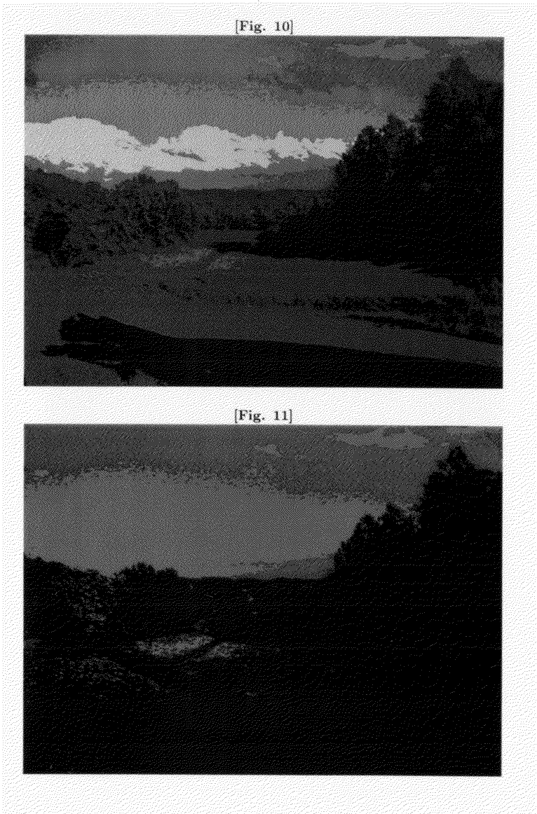

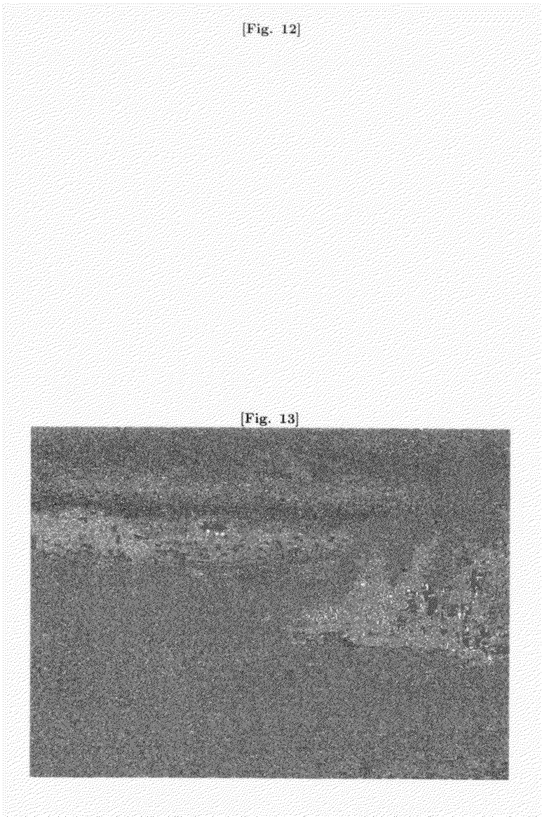

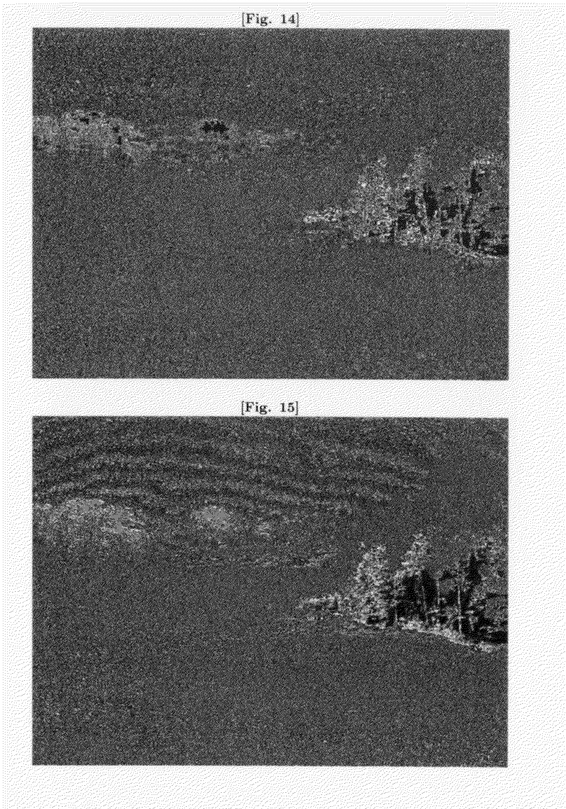

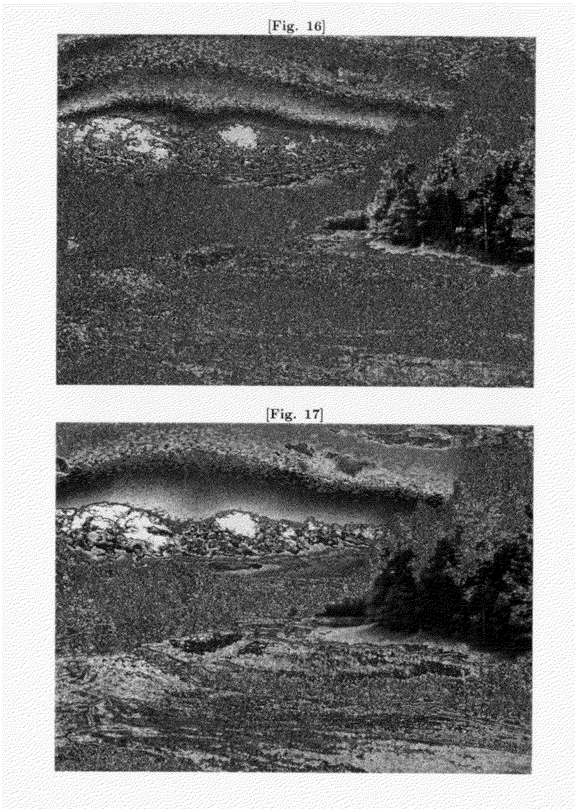

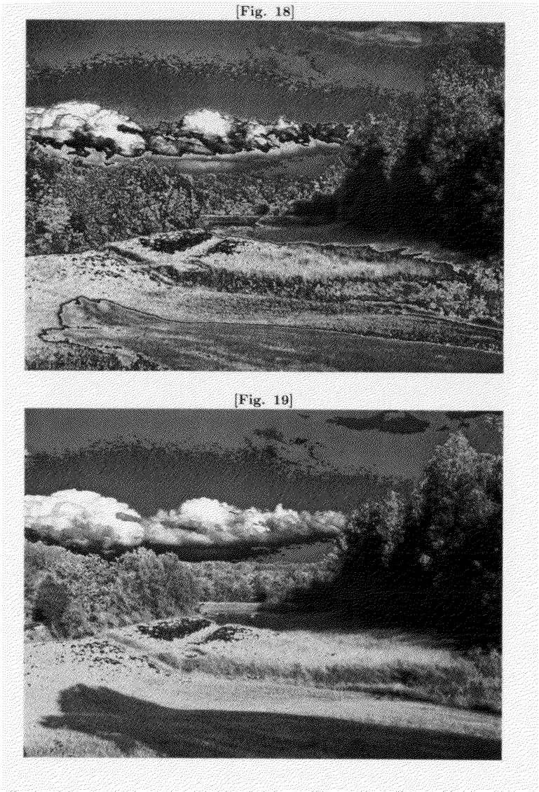

The previous example, a simple geometric signal in the presence of noise, was constructed to showcase the advantage of critical data compression. We now perform a similar analysis using a color photograph. We partition each of the image's red, green, and blue channels into their most and least significant bits. The resulting channels may be viewed below, three per image. This time we omit the no-signal (n=0 signal) image for brevity, as the absence of a signal simply appears black. [FIG. 4] [FIG. 5] [FIG. 6] [FIG. 7] [FIG. 8] [FIG. 9] [FIG. 10] [FIG. 11] [FIG. 12] [FIG. 13] [FIG. 14] [FIG. 15] [FIG. 16] [FIG. 17] [FIG. 18] [FIG. 19]

We are now ready to calculate the critical depth of the color image. For simplicity, we treat the red, green, and blue channels as being independent tensors. The image is 1280×960, so each bit of color depth corresponds to 1228800 bits of data. It had been previously compressed with the JPEG algorithm but this doesn't matter for purposes of illustration—when a more developed approach is evaluated against the mean-squared error of JPEG2000, we will use uncompressed test images. The Aⁿ are again compressed using gzip until compressing an additional bit of sample depth would increase storage requirements by more than 1228800 bits. We will start with the red channel. For n=0-8, K(Aⁿ)=0, 188592, 494256, 1102656, 1735776, 3343584, 4835008, 7774896, 8085728.

Allowing a 25 percent tolerance, the first-order critical depth occurs at n=7 and the second-order critical depth occurs at n=6. Now we consider the green channel. For n=0-8, K(Aⁿ)=0, 121616, 427232, 1038880, 1643968, 3161216, 4606128, 7374720, 7764240.

Again, the first-order critical depth occurs at n=7 and the second-order critical depth occurs at n=6. Finally, consider the blue channel. For n=0-8, K(Aⁿ)=0, 51904, 328880, 839072, 1655376, 2961680, 4423184, 7124752, 7902688.

The result is the same, the first-order critical depth occurs at n=7 and the second-order critical depth occurs at n=6. We store a critically compressed representation at the second-order critical depth of 6. Alternately, the complexity of all three channels can be considered simultaneously by compressing the entire image.

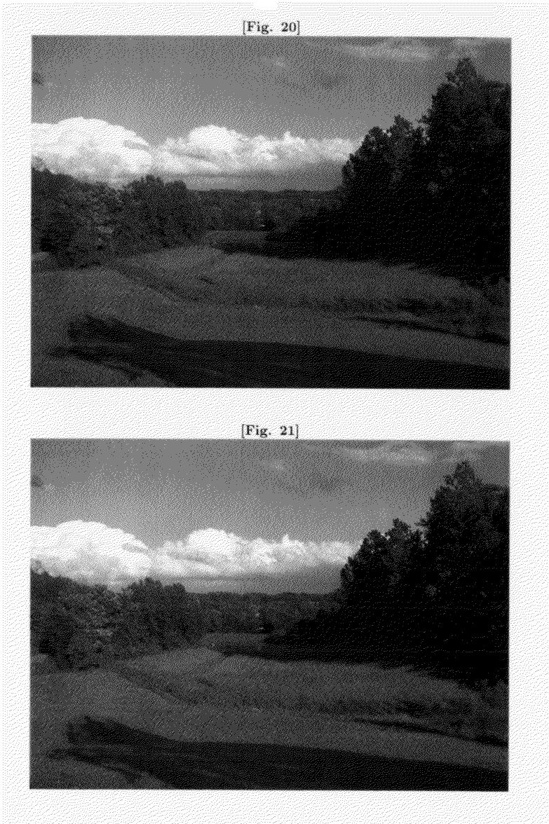

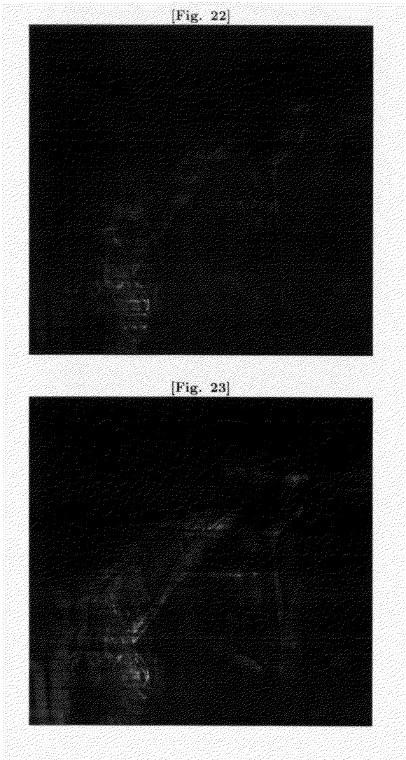

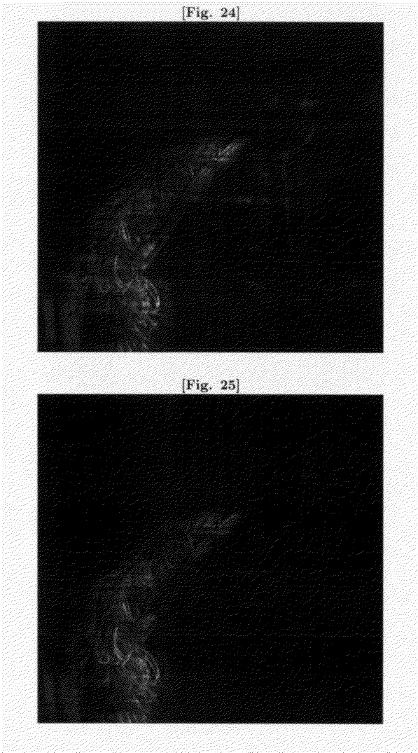

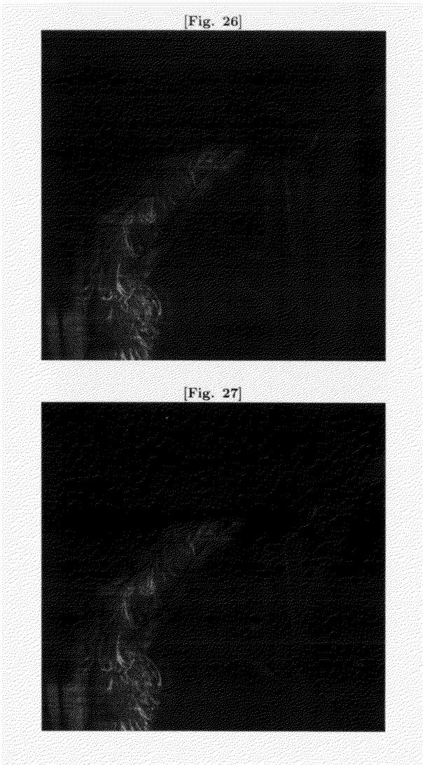

Having determined the critical points and stored the associated signal, we are ready to compress its residual noise function. The critical noise function is compressed using a JPEG algorithm to 134,732 bytes. The critical signal, compressed via gzip with all three channels in one file, occupies 1,495,987 bytes, which saves 237,053 bytes over compressing the channels separately. Combined, the critical signal and its residual noise occupy 1,630,719 bytes. The original image occupies 3,686,400 bytes. As such, this simplistic implementation of critical compression leads to a compression ratio of just 2.26:1, however, it is essentially indistinguishable (its mean-squared error is just 3.09) from the original image, as may be verified below. [FIG. 20]

The gzip algorithm used to estimate complexities to this point is typical of most lossless data compression in use today, being optimized for speed rather than the highest possible compression ratios. Naturally, slower but more effective lossless compression will produce estimates closer to the true complexities, leading to better compression and improved inference.

In order to obtain highly compressed lossless codes, we now switch to another algorithm, PAQ81, which trains and arithmetically codes a neural net which makes linear combinations of nearby pixels or samples. In this case we encode all three channels of the signal at each bit depth n into a file and apply PAQ using its maximum compression. In this case, since there are 3 channels at 1280×960, each bit of channel depth constitutes 1,228,800 bits of raw data. For n=0-8, K(Aⁿ)=0, 14552, 168912, 328880, 1279152, 2397944, 4015184, 6332896, 9211368, 11844400.

To illustrate why Kolmogorov's criterion of randomness does not produce a minimal sufficient statistic in this case, we present the derivative (slope) of complexity with respect to literal description length. In this case, the slope (which is simply ∂ₜK(A) normalized by length(A) to [0, 1]) never reaches 1 since even the least significant bits compress by a third or more. This indicates correlation between the three channels. For n=1-8, the slopes are 0.0434, 0.0893, 0.2578, 0.3035, 0.4387, 0.6287, 0.7808, 0.7143.

This exhibits behavior typical of phase transitions, a sigmoidal form that rises from about 0.04 to over 0.7 as n rises from 0 to 8. Even so, the complexity estimates are not perfect. To determine the first-order critical depth, we treat measurements within a 25% tolerance of the maximum value of 0.78084—measurements greater than 0.58563—as elements of the maximal set. This criterion is satisfied at depths 6, 7, and 8, so we select the minimum complexity from this set. Hence, the first-order critical depth is 6.

By considering the second partial derivative of complexity, the slope of the slope function, using a central difference approximation, we may determine the critical point at which the phase transition proceeds most rapidly. Since the phase transition is relatively broad, one might expect several points to be close to the maximum rate. For n=1-7, the slope of the slope is 0.0458, 0.1686, 0.0471, 0.1352, 0.1900, 0.1521, −0.0666.

The maximum (0.1900) occurs at depth n=5. If we use 25% tolerance, as before, then the cutoff for the maximum set becomes 0.1425075, so its members occur at n=3, n=5, and n=6. The least complex element in this maximal set determines the second-order critical depth, which in this case is n=3. This differs significantly from the result obtained using the lower compression levels of grip, demonstrating the importance of high-quality lossy codes in a critical compression scheme.

We encode the residual noise associated with depth 3 using the JPEG2000 algorithm, which is generally regarded as being slower but higher in quality than JPEG. For the purposes of constructing critical codes, JPEG2000 has superior properties of convergence to the original image, as compared to JPEG. Using the Jasper library to compress the noise function at 50:1, the length of our improved depth 3 second-order critical representation is shown below improves to 258,061, while its mean-squared error is about 100, which is typical of broadcast images. The image is shown below, with the original for comparison. [FIG. 21]

This simple example shows that critical codes are competitive with the prevailing algorithms for image compression. A more rigorous determination of the mean squared errors of a variety of standard, uncompressed test images, shows that two part codes actually outperform JPEG2000 for many types of images under this metric. For images which are not traditional color photographs, the advantage of a critical representation is often significant, demonstrating that two-part codes could be utilized to improve the performance of a wide variety of applications.

### Example 2

In addition to the utility normally associated with a more parsimonious representation, the resulting image is more useful in pattern recognition. This aspect of the invention is readily demonstrated using a simple example of image pattern recognition.

Critical signals are useful for inference for several reasons. On one hand, a critical signal has not experienced information loss—particularly, edges are preserved better since both the ‘ringing’ artifacts of non-ideal filters (the Gibbs phenomenon) and the influence of blocking effects are bounded by the noise floor. On the other hand, greater representational economy, compared to other bit depths, translates into superior inference.

We will now evaluate the simultaneous compressibility of signals in order to produce a measure of their similarity or dissimilarity. This will be accomplished using a sliding window which calculates the conditional prefix complexity K(A|B)=K(AB)−K(B), as described in the earlier section regarding artificial intelligence.

In order to begin, we must first decide how to combine signals A and B into the simultaneous signal AB. When processing textual data, the classic solution would be to concatenate the string representations of A and B. With image data, other solutions are conceivably viable. For instance, the images could be averaged or interlaced rather than simply concatenated. However, numerical experiments reveal that simple concatenation results in superior compression performance. This translates naturally into superior inference.

We will now calculate distance functions and convert them into pattern-specific filters for purposes of visualization. The dimensions (x by y) of the texture B and the matrix representation of its distance function Dₘₙ(A,B) are used as input to construct a filter ƒₘₙ selecting regions of image A that match pattern B. In order to match the search space, the coordinates of the distance function associated with the sliding window is translated to the center of the window. Each pixel in the filter assumes the value of one minus Dₘₙ(A,B), where

$$m + ⌈ \frac{x}{2} ⌉ , n + ⌈ \frac{y}{2} ⌉$$

is the center of the window closest to that pixel. Since the distance function is not defined on the boundaries of the image, the closest available distance function may not be a good estimate, and distance estimates on the boundary should be regarded as being approximate, or omitted entirely. They are shown in the examples for demonstrative purposes.

Multiplying pixels in the image A by the filter (ƒₘₙ(A,B)Aₘₙ) has the effect of reproducing pixels that match the pattern while zeroing pixels that do not match. Applying the filter multiple times (or exponentiating it) will retain the most similar regions and deemphasize less similar regions. Alternately, one could apply a threshold to this function to produce a binary-valued filter denoting a pixel's membership or non-membership in the pattern set.

Using this visualization, we will see that the second order critical depth leads to better inference than the other bit depths. If too much bit depth is used, there may be enough data to identify periodicity where it exits, overemphasizing matches similar to particular instances in the texture. If bit depth is insufficient, many samples become equivalent to one another, leading to false positive matches. This notion is similar to the considerations involved in ‘binning’ sparse data into histograms—if bins are too large, corresponding to insufficient bit depth, the histogram is too smooth and useful information is lost. If the bins are too small, corresponding to excess bit depth, then there aren't enough statistics, leading to sample noise and significant error in the resulting statistics. Ideally, we wish to have all the bit depth relevant to inference without including the superfluous data that tend to confound the inference process, and we will demonstrate that this occurs near the second-order critical depth, as one might expect, given its representational economy.

We will perform inference using the famous ‘Lena’ test image, which is ‘lena3’ among the Waterloo test images. The image is 512×512 and has three channels of 8-bit color. As a simple example of image recognition, we will crop a sample texture from the lower 12 rows of the image, leaving a 512×500 image to generate our search space. The search texture is taken from a rectangle extending between coordinates (85,500) and (159,511) in the original test image, using 0-based indexes, giving it dimensions of 75×12. We wish to compare this texture (it samples the tassel attached to Lena's hat) against our search space, the set of rectangles in the cropped image, by estimating the conditional prefix complexity of the texture given the contents of each sliding window.

For reasons of computational expense, it may not be possible to evaluate complexity at every point in the search space. For some applications, only the extremum is of interest, and nonlinear optimization techniques may be applied to search for this extremum. In the case at hand, however, we wish to visualize the distance function over the entire search space, so we simply sample the distance function at regular intervals. In this example, we will evaluate the distance function at points having even coordinates.

Though this exercise illustrates distance functions at each bit depth, which should make superior inference subjectively apparent, we also wish to estimate the second-order critical depth. This will demonstrate that the signal which we expect a priori to be the most economical also leads to superior inference. We will start by estimating the complexity of the original 512×512 Lena image. For bit depths n=0-8, K(Aⁿ)=452, 23515, 43465, 74632, 118824, 188461, 284150, 384018, 482483.

If we allow a 25% tolerance factor within the maximum set, as before, we see that the first-order critical point is at depth 6 and the second order critical point is at depth 4. We will see that inference at depth 4 outperforms inference at lower or higher bit depths, as predicted.

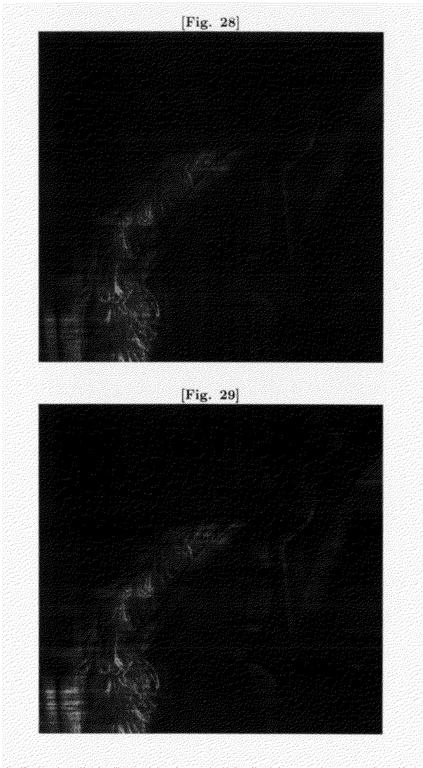

A sliding window is applied to the image to produce string B, and the conditional prefix complexity K(A|B)=K(AB)−K(B) is calculated. This is done for signals having bit depths of 1 through 8. For visibility, the resulting filter is applied to the image four times and the resulting image is normalized to 100% intensity. The result follows. [FIG. 22] [FIG. 23] [FIG. 24] [FIG. 25] [FIG. 26] [FIG. 27] [FIG. 28] [FIG. 29]

### Example 3

Another possible embodiment of the invention compresses the critical bits of a data object losslessly, as before, while simultaneously compressing the entire object using lossy methods, as opposed to lossy coding only an error or residual value. In principle, this results in the coding of redundant information. In practice, however, the lossy coding step is often more effective when, for example, an entire image is compressed rather than just the truncated bits. Encoding an entire data object tends to improve prediction in the lossy coder, while encoding truncated objects often leads to the high spatial frequencies which tend to be lost during lossy coding. Such a redundant lossy coding of the original data often results in the most compact representation, making this the best embodiment for many applications relating to lossy coding. This may not always be the case, for instance, when the desired representation is nearly lossless such a scheme may converge more slowly than one encoding truncated data. On the other hand, however, this scheme is simple generally applicable to any type of lossy coding, whereas greater care must be taken when lossy coding truncated data (in video data, for instance) to avoid introducing high-frequency artifacts and noise to the data.

Compressing and decompressing data using this embodiment is simpler than critically compressing data via truncation, as no normalization needs to be performed. Once the desired critical bit depth has been selected, the original data's precision is reduced from the original bit depth of d to the critical bit depth of n and the resulting object is coded losslessly, as before, while the original data is simultaneously coded using lossy compression. As before, this operation may take place on a channel-by-channel basis with arbitrary parameters and with data having undergone an arbitrary set of transformations, e.g. color space rotations.

Upon decompression, the lossless code is used to establish exact upper and lower bounds for lossy compression. The lossless code establishes a lower bound since the truncated values never exceed the original values. Likewise, since 2^{d-n}−1 is the largest quantity which could have be truncated, adding this to the reduced-precision data produces an upper bound on any value which could be truncated to produce the losslessly coded reduced-precision data.

The decompression scheme is as follows: If the n leading bits of the value predicted by the lossy code match the lossless code, the value predicted by the lossy code is returned as the decompressed datum. If the n leading bits predicted by the lossy code are less than the value coded by the lossless code, the value of the lossless code is returned as the decompressed datum since it is a lower bound on the original value. Otherwise, if the n leading bits predicted by the lossy code are greater than the value coded by the lossless code, the value coded by the lossless code is increased by 2^{d-n}−1 and returned as the decompressed datum since this is an upper bound on the value of the original data.

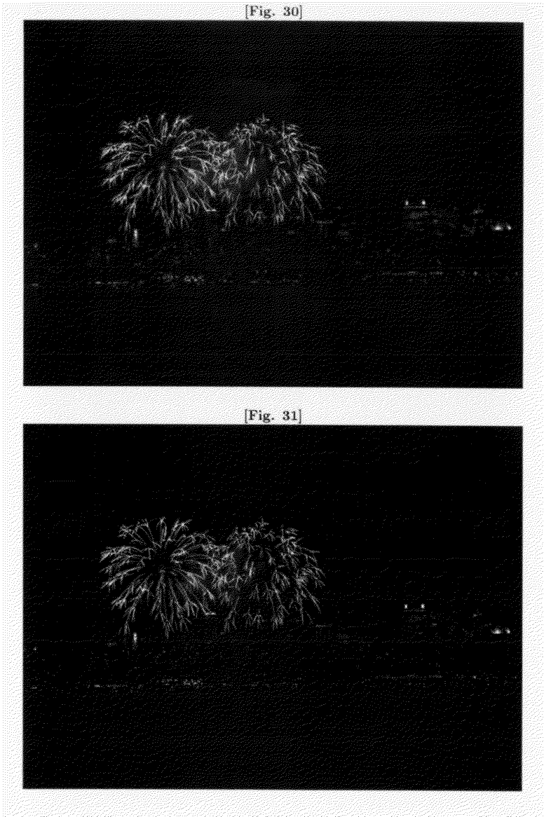

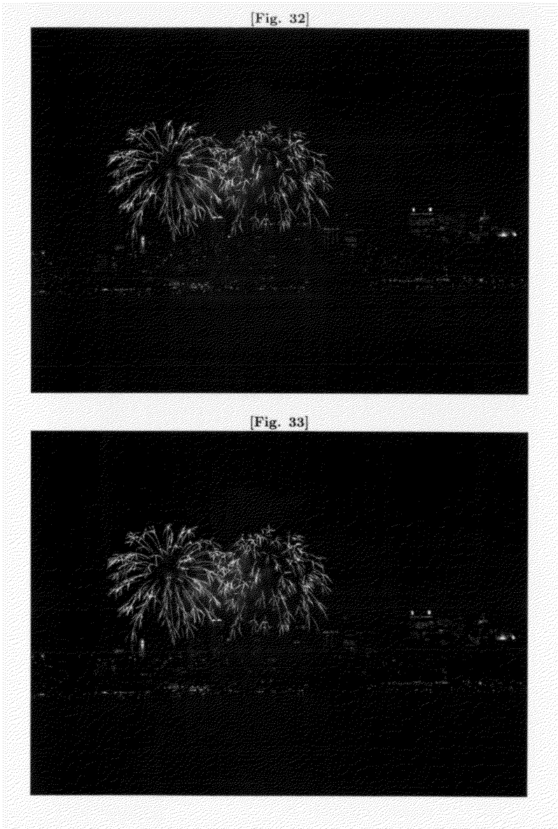

As an example of this approach, we will consider the critical compression of another test image, the 8-bit (per channel) RGB color ‘fireworks’ image from ‘The New Test Images’, which is 3136 by 2152 pixels, which is 20,246,016 bytes of raw data. We will compress the image in YCC space, with the luminance channel being critically compressed at a bit depth of 4 and chrominance data is taken from the lossy compression. Two objects are stored, one is a JPEG2000 compressed version of the original RGB color space image (which uses a YCC color space internally) whose compression ratio is 1000:1 and the other is a PAQ-compressed lossless representation of a luminance (Y) channel whose precision has been reduced from an 8-bit (256 shade) grayscale image to a 4-bit (16 shade) grayscale image. The JPEG2000 representation of the original image may be seen in FIG. 30, the lossless representation of a 4-bit luminance channel derived from the original image in FIG. 31, and the original image is shown in FIG. 32 for comparison. [FIG. 30] [FIG. 31] [FIG. 32]

During decompression, the luminance value implied by the color of each pixel in the JPEG2000 channel is compared to the 4-bit luminance channel. The largest possible truncation error in the 4-bit luminance channel is 15, so the luminance should be between the value coded by the 4-bit lossless channel and this value increased by fifteen. If the luminance predicted by the lossy JPEG2000 code falls within this range, then the color predicted by JPEG2000 is used for the pixel. If the JPEG2000-predicted luminance falls below this range, then the value coded by the 4-bit lossless channel is used for the luminance, being combined with the chrominance values implied by the JPEG2000-predicted color value before being rotated back into the RGB color space. If the JPEG2000-predicted luminance falls above the allowed range, then the value coded by the 4-bit lossless channel is increased by fifteen before used for the luminance and combined with the chrominance values implied by the JPEG2000-predicted color and being rotated back into the RGB color space. The decompressed image resulting from this coding and decoding scheme may be seen below. [FIG. 33]

Examination of this image reveals that the absolute bounds obtained from lossless brightness values have greatly increased the contrast of the resulting picture as compared to the JPEG2000 representation.

1. A method of representing compressed numerical data, the compressed representation being comprised of an information-losing ('lossy') representation of the numerical data, and also being comprised of a lossless representation of the numerical data which is truncated, rounded, or otherwise reduced in precision and/or scale; upon decompression of this compressed representation, the most significant bits of each value are taken from the lossless coding but the least significant bits are predicted using the lossy representation, one embodiment of such decompression would be to use the lossy coded value if the lossy code predicts a value between the lossless coded value and the sum of the lossless coded value and the maximum possible truncated value, to use the lossless coded value if the lossy code predicts a value less than the lossless coded value, and to use the sum of the lossless coded value and the maximum possible truncated value if the lossy code predicts a value greater than the sum of the lossless coded value and the maximum possible truncated value.

2. A method of representing compressed numerical data, the compressed representation being comprised of an information-losing (‘lossy’) representation of the least significant bits which is proportional to the residual or error arising from truncating, rounding, or otherwise reducing the precision and/or scale of the numerical data, and also being comprised of a lossless representation of the numerical data having reduced precision and/or scale; upon decompression of this compressed representation the lossless and lossy representations are combined to produce data similar to the original numerical data, one embodiment of such decompression would be to decode and optionally rescale the lossy representation before summing it with the decoded lossless representation.

3. Utilizing the length of a compressed representation to perform inference (for example, by applying the minimum description length principle for the purpose of pattern recognition) when the compressed representation is comprised of numerical data having its precision reduced to a level which optimizes some function of the economy of its representation (for example, by compressing additional bits of precision until the data requirement of compressing additional bits of precision exceeds some threshold).
